(19) United States
(12) Patent Application Publication
(10) Pub. No.: US 2026/0225926 A1
(43) Pub. Date: Aug. 6, 2026

(54) SUBSTRATE PROCESSING APPARATUS AND SUBSTRATE PROCESSING METHOD

(71) Applicant: SCREEN Holdings Co., Ltd., Kyoto (JP)

(72) Inventors: Michinori IWAO, Kyoto-shi, Kyoto (JP); Hiroaki KAMON, Kyoto-shi, Kyoto (JP); Shota IWAHATA, Kyoto-shi, Kyoto (JP)

(21) Appl. No.: 19/150,167

(22) PCT Filed: Feb. 1, 2024
(86) PCT No.: PCT/JP2024/003237

§ 371 Date: Jul. 22, 2025

(30) Foreign Application Priority Data
Feb. 15, 2023 (JP) 2023-021729

(51) Int. Cl. C02F 1/467; C02F 1/00; C02F 1/461; C02F 101/30; C02F 103/34; C09K 13/04; G03F 7/42; H10P 72/00

(52) U.S. Cl. CPC C02F 1/4672; C02F 1/004; C02F 1/46104; C09K 13/04; G03F 7/423; H10P 72/0414; C02F 2101/30; C02F 2103/346; C02F 2201/46185; C02F 2301/08

(57) ABSTRACT

A substrate processing apparatus includes a nozzle that is supplied with first solution containing a peroxydisulfate ion and supplies treatment solution containing the first solution to a substrate, a first tank that stores the first solution, a second tank that is supplied with waste solution, which is the treatment solution after being used for processing on the substrate, and stores second solution, a first path through which the second solution circulates to and from the second tank, and in which third solution is generated by performing first electrolysis on the second solution, a second path including a filter, in which the first solution is generated by performing second electrolysis while the third solution is filtered by the filter, and a third path for supplying the first solution to the first tank.

### TECHNICAL FIELD

The present disclosure relates to a technique for processing a substrate. Substrates to be subjected to the processing (hereinafter referred to as “substrate processing”) include, for example, a semiconductor wafer, a glass substrate for a liquid crystal display apparatus, a substrate for a flat panel display (FPD) such as an organic electroluminescence (EL) display apparatus, a substrate for an optical disk, a substrate for a magnetic disk, a substrate for a magneto-optical disk, a glass substrate for a photomask, a ceramic substrate, a substrate for a field emission display (field emission display, that is, FED), a substrate for a solar cell, or the like.

### BACKGROUND ART

As treatment solution used for substrate processing, for example, mixed liquid of sulfuric acid (H₂SO₄) and hydrogen peroxide solution (H₂O₂), which is commonly called a sulfuric acid-hydrogen peroxide mixture (SPM), is publicly known (see, for example, Patent Document 1 below). In an SPM, peroxymonosulfuric acid (H₂SO₅) is generated and used, for example, to remove resist formed on a surface of a substrate.

Use of a peroxydisulfate ion (S₂O₈²⁻) as an active species (etchant) in substrate processing is publicly known. For example, Patent Document 2 discloses a technique using mixed solution (sulfuric ozone peroxide mixture: SOM) of sulfuric acid and ozone in order to obtain a peroxydisulfate ion.

### PRIOR ART DOCUMENT

### Patent Documents

Patent Document 1: Japanese Patent Application Laid-Open No. 2020-47857
Patent Document 2: Japanese Patent Application Laid-Open No. 2022-188425

### SUMMARY

### Problem to be Solved by the Invention

Treatment solution after being used for substrate processing (hereinafter referred to as “waste solution”) contains a large amount of organic substances as compared with treatment solution before being used for substrate processing. Generation (hereinafter, also referred to as “regeneration” or “regeneration processing”) of treatment solution using recovered waste solution is introduced in, for example, Patent Document 1.

Performing substrate processing in a state where treatment solution contains an organic substance may cause contamination of a substrate in the substrate processing, particularly adhesion of a particle. Therefore, the organic substance is desirably removed in the regeneration processing.

For example, filtration by a filter is used for the removal. Removing an organic substance in the regeneration only by a filter has a problem of shortening life of the filter.

In view of the above problem, the present application discloses a technique for extending life of a filter that removes an organic substance from the waste solution in the regeneration processing.

### Means to Solve the Problem

A substrate processing apparatus according to the present disclosure is an apparatus that performs processing on a substrate by using treatment solution. A first aspect of the substrate processing apparatus includes a nozzle that is supplied with first solution containing a peroxydisulfate ion and supplies the treatment solution containing the first solution to the substrate, a first tank that stores the first solution, a second tank that is supplied with waste solution, which is the treatment solution after being used for the processing on the substrate, and stores second solution, a first path through which the second solution circulates to and from the second tank, and in which third solution is generated by performing first electrolysis on the second solution, a second path including a filter, in which the first solution is generated by performing second electrolysis while the third solution is filtered by the filter, and a third path for supplying the first solution to the first tank.

A second aspect of the substrate processing apparatus according to the present disclosure is the first aspect of the substrate processing apparatus, in which the first path includes a first electrolyzer that performs the first electrolysis. The second path includes a third tank that stores the third solution, and a second electrolyzer in which the third solution circulates to and from the third tank, the second electrolyzer performing the second electrolysis.

A third aspect of the substrate processing apparatus according to the present disclosure is the first aspect of the substrate processing apparatus, in which the second tank is included in both the first path and the second path. The third solution circulates to and from the second tank in the second path.

A fourth aspect of the substrate processing apparatus according to the present disclosure is the third aspect of the substrate processing apparatus, in which the first path includes a first electrolyzer that performs the first electrolysis. The second path includes a second electrolyzer that performs the second electrolysis.

A fifth aspect of the substrate processing apparatus according to the present disclosure is the third aspect of the substrate processing apparatus, in which the second path further includes a first on-off valve connected in series to the filter. The first path includes a second on-off valve provided in parallel to series connection of the filter and the first on-off valve, and an electrolyzer also shared by the second path. The electrolyzer performs the first electrolysis when the first on-off valve is closed and the second on-off valve is opened, and performs the second electrolysis when the second on-off valve is closed and the first on-off valve is opened.

A sixth aspect of the substrate processing apparatus according to the present disclosure is any of the first to fifth aspects of the substrate processing apparatus, in which the second electrolysis is executed at higher temperature than the first electrolysis.

A substrate processing method according to the present disclosure is a method of performing processing on a substrate by using treatment solution, the substrate processing method including a step of supplying the treatment solution containing first solution containing a peroxydisulfate ion to the substrate, a step of supplying waste solution, which is the treatment solution after being used for the processing on the substrate, to a tank that stores second solution, a step of generating third solution by performing first electrolysis on the second solution in a first path through which the second solution circulates to and from the tank, and a step of generating the first solution by performing second electrolysis while filtering the third solution by the filter in a second path including a filter.

### Effects of the Invention

The first aspect of the substrate processing apparatus and the substrate processing method according to the present disclosure contribute to prolonging life of a filter that removes an organic substance from waste solution in regeneration processing. The second aspect and the fourth aspect of the substrate processing apparatus contribute to suppression of deterioration of the electrolyzer. The fifth aspect of the substrate processing apparatus is easily realized at low cost.

### BRIEF DESCRIPTION OF DRAWINGS

FIG. 1 is a block diagram schematically illustrating a configuration of a substrate processing apparatus according to the present disclosure.

FIG. 2 is a schematic diagram exemplifying a configuration of a supply and recovery unit.

FIG. 3 is a schematic diagram exemplifying a configuration of a processing unit.

FIG. 4 is a schematic diagram schematically exemplifying a processing unit and a related configuration.

FIG. 5 is a cross-sectional view exemplifying an internal structure of a nozzle.

FIG. 6 is a schematic diagram exemplifying a configuration of a discharge unit.

FIG. 7 is a block diagram conceptually exemplifying a configuration of a control unit.

FIG. 8 is a schematic diagram exemplifying a configuration of a first recovery unit.

FIG. 9 is a schematic diagram exemplifying a configuration of a first sulfuric acid electrolysis unit.

FIG. 10 is a schematic diagram exemplifying a configuration of a second recovery unit.

FIG. 11 is a schematic diagram exemplifying a configuration of a second sulfuric acid electrolysis unit.

FIG. 12 is a schematic diagram exemplifying a configuration of a third sulfuric acid electrolysis unit.

FIG. 13 is a flowchart exemplifying regeneration processing.

### DESCRIPTION OF EMBODIMENTS

Hereinafter, an embodiment will be described with reference to the accompanying drawings. In an embodiment below, a detailed feature and the like are also shown for explanation of a technique, but they are merely examples, and not all of them are necessarily essential features for enabling the embodiment to be carried out.

The drawings are shown schematically, and for convenience of explanation, a configuration is omitted or a configuration is simplified or the like on the drawings as appropriate. Further, an interrelationship between sizes and positions of configurations and the like shown in different drawings is not always accurately described and may be changed as appropriate. Further, hatching may be applied to a drawing such as a plan view that is not a cross-sectional view in order to facilitate understanding of content of an embodiment.

In the drawings, in a case where pipes are drawn to intersect in a Y shape or a T shape, unless otherwise specified, it indicates that three pipes drawn linearly communicate with each other. In the drawings, in a case where pipes are drawn to intersect in an X shape or a cross shape, unless otherwise specified, it indicates that two pipes drawn linearly through an intersection point do not communicate with each other.

An arrowhead added to a line drawn as a pipe in the drawings indicates a direction in which fluid flows.

In description shown below, similar constituent elements are denoted by the same reference numerals, and names and functions of these are similar. Therefore, there is a case where detailed description of them is omitted to avoid duplication.

In description described in the description of the present application, in a case where description of “comprising”, “including”, or “having” a certain constituent or the like is shown, such an expression is not an exclusive expression for excluding the presence of other constituents unless otherwise specified.

In description described in the description of the present application, even if ordinal numbers such as “first” or “second” are used, these terms are used for convenience to facilitate understanding of content of the embodiment, and the content of the embodiment is not limited to order or the like that may be caused by these ordinal numbers.

In description described in this description, even in a case where terms meaning specific positions or directions such as “upper”, “lower”, “left”, “right”, “side”, “bottom”, “front”, or “back” are used, these terms are used for convenience to facilitate understanding of content of an embodiment, and are not related to positions or directions when the embodiment is actually implemented.

In description described in the present description, in a case where “upper surface of . . . ”, “lower surface of . . . “, or the like is described, it is intended to include a state in which another constituent element is formed on an upper surface or a lower surface of a target constituent element in addition to the upper surface itself or the lower surface itself of the target constituent element. That is, for example, in a case where “B provided on an upper surface of A” is described, interposition of another constituent element “C” between A and B is not excluded.

### <1. Overview of Substrate Processing Apparatus 1>

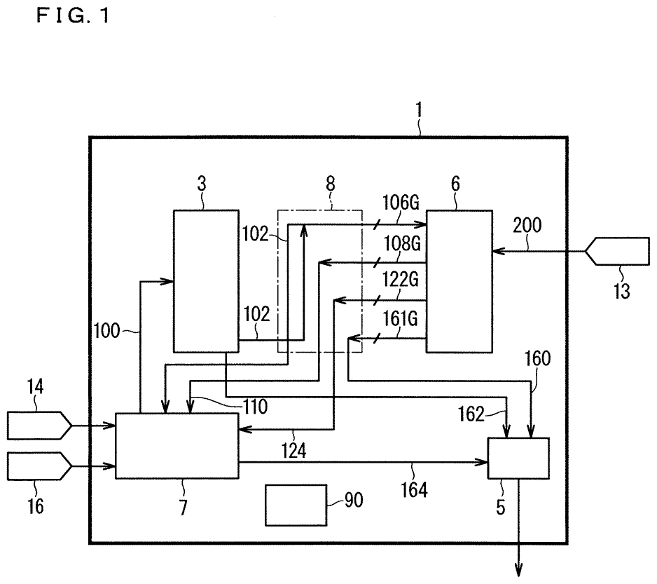

FIG. 1 is a block diagram schematically illustrating a configuration of a substrate processing apparatus 1 according to the present disclosure.

The substrate processing apparatus 1 includes a supply and recovery unit 3, a discharge unit 5, a processing unit 6, a regeneration unit 7, recovery pipes 110 and 124, a discharged liquid pipe 160, and a control unit 90.

### <1-1. Supply and Recovery Unit 3>

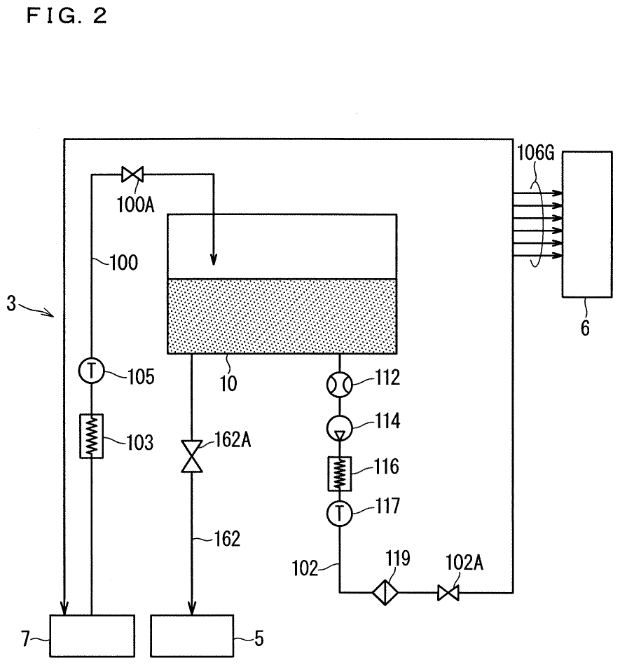

FIG. 2 is a schematic diagram exemplifying a configuration of the supply and recovery unit 3. The supply and recovery unit 3 has a function of supplying and recovering first solution to and from the processing unit 6. The processing unit 6 performs substrate processing. The first solution contains a peroxydisulfate ion, typically peroxydisulfuric acid (H₂S₂O₈). As described later, concentration of peroxydisulfuric acid in the first solution is desirably high.

The supply and recovery unit 3 includes a supply tank 10, supply pipes 100 and 102, a discharged liquid pipe 162, valves 100A, 102A, and 162A, a flow meter 112, a pump 114, heaters 103 and 116, thermometers 105 and 117, and a filter 119.

As described later, the first solution (hereinafter, also referred to as “post-regeneration sulfuric acid”) regenerated by the regeneration unit 7 flows through the supply pipe 100. Post-regeneration sulfuric acid is supplied from the supply pipe 100 to the supply tank 10.

The supply tank 10 functions as a first tank that stores the first solution. The valve 100A is provided in the supply pipe 100, and adjusts a flow rate of post-regeneration sulfuric acid flowing through the supply pipe 100 under control of the control unit 90.

A supply pipe group 106G communicates with the supply pipe 102. The supply pipe 102 has a function of supplying the first solution to the processing unit 6 via the supply pipe group 106G.

The flow meter 112, the pump 114, the heater 116, the thermometer 117, the filter 119, and the valve 102A are provided in series in the supply pipe 102, for example, in this order.

The thermometer 117 measures temperature of the first solution flowing through the supply pipe 102. The heater 116 heats the first solution so that temperature measured by the thermometer 117 is, for example, 90° C. Such temperature adjustment is performed under control of the control unit 90.

The filter 119 removes a foreign substance, for example, a particle, in the first solution flowing through the supply pipe 102.

The pump 114 pressurizes the first solution in the supply pipe 102 from a bottom portion of the supply tank 10 to the side opposite to the supply tank 10. By such pressurization, the first solution flows from a bottom portion of the supply tank 10 to the supply pipe group 106G via the supply pipe 102. Of the first solution flowing through the supply pipe 102, a portion that does not flow to the supply pipe group 106G is supplied to the regeneration unit 7.

The control unit 90 grasps substrate processing performed by the processing unit 6 with reference to a processing recipe. A flow rate of the first solution flowing through the supply pipe 102 is adjusted by, for example, opening degree of the valve 102A such that a flow rate of the first solution measured by the flow meter 112 becomes a flow rate sufficient for the substrate processing. The adjustment of the valve 102A is performed under control of the control unit 90.

The discharged liquid pipe 162 has a function of discharging the first solution from the supply tank 10. The valve 162A is provided in the discharged liquid pipe 162, and adjusts a flow rate of the first solution flowing through the discharged liquid pipe 162 under control of the control unit 90. The first solution discharged from the supply tank 10 through the discharged liquid pipe 162 is supplied to the discharge unit 5.

The thermometer 105 measures temperature of the first solution flowing through the supply pipe 100. The heater 103 heats the first solution so that temperature measured by the thermometer 105 is, for example, 90° C. Such temperature adjustment is performed under control of the control unit 90.

### <1-2. Recovery Pipes 110 and 124 and Discharged Liquid Pipe 160>

A return pipe group 108G communicates with the recovery pipe 110. The first solution supplied from the supply pipe group 106G but not used for substrate processing flows into the return pipe group 108G. The first solution flows into the recovery pipe 110 from the processing unit 6 via the return pipe group 108G. The first solution flowing into the recovery pipe 110 is supplied to the regeneration unit 7.

A waste solution pipe group 122G communicates with the recovery pipe 124. Waste solution (hereinafter, also referred to as “first waste solution”) used for first substrate processing described later flows into the waste solution pipe group 122G. The first waste solution flows into the recovery pipe 124 from the processing unit 6 via the waste solution pipe group 122G. The first waste solution flowing into the recovery pipe 124 is supplied to the regeneration unit 7. Supply of the first waste solution to the regeneration unit 7 can be regarded as recovery of the first waste solution from the processing unit 6 to the regeneration unit 7.

In the regeneration unit 7, the first solution is obtained from the recovered first waste solution by regeneration processing described later. The regeneration processing reduces chemical solution newly supplied to the substrate processing apparatus 1 and the first waste solution discharged from the substrate processing apparatus 1, allows resources to be more efficiently used, and contributes to an environmentally friendly technique and production method.

A waste solution pipe group 161G communicates with the discharged liquid pipe 160. Waste solution (hereinafter, also referred to as “second waste solution”) used for second substrate processing described later flows into the waste solution pipe group 161G. The second waste solution flows into the discharged liquid pipe 160 from the processing unit 6 via the waste solution pipe group 161G. The second waste solution flowing into the discharged liquid pipe 160 is supplied to the discharge unit 5.

The recovery pipes 110 and 124 and the discharged liquid pipe 160 are arranged, for example, in a pipe space 8. The pipe space 8 is provided, for example, between a position where the supply and recovery unit 3 is arranged and a space where the processing unit 6 is arranged. In the pipe space 8, the supply pipe group 106G communicates with the supply pipe 102, the return pipe group 108G communicates with the recovery pipe 110, the waste solution pipe group 122G communicates with the recovery pipe 124, and the waste solution pipe group 161G communicates with the discharged liquid pipe 160.

### <1-3. Processing Unit 6>

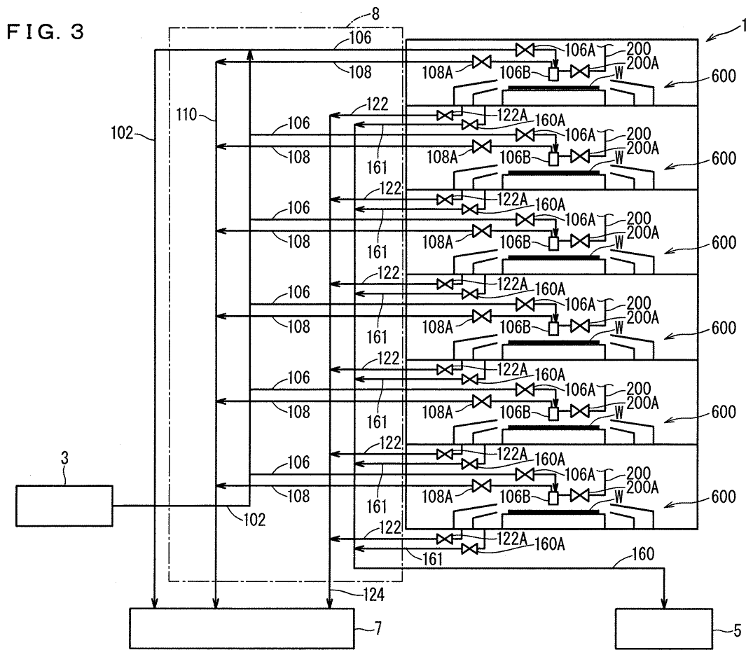

FIG. 3 is a schematic diagram exemplifying a configuration of the processing unit 6. The processing unit 6 has a plurality (six in the example of FIG. 3) processing units 600.

The substrate processing method by the substrate processing apparatus 1 includes a step of dispensing treatment solution onto a substrate W conveyed to the processing unit 600 to perform substrate processing, a step of cleaning the substrate W on which the substrate processing is performed, a step of rotating and drying the cleaned substrate W, and a step of carrying out the dried substrate W from the processing unit 600. These steps are performed by control of operation of each configuration (for example, a pump, a heater, a valve, or a spin motor) in the substrate processing apparatus 1 by the control unit 90.

Each of the processing units 600 has valves 106A, 108A, 122A, 160A, and 200A and a nozzle 106B. A supply pipe 106, a return pipe 108, waste solution pipes 122 and 161, and a mixing pipe 200 are introduced into each of the processing units 600. A plurality of the supply pipes 106 constitute the supply pipe group 106G, a plurality of the return pipes 108 constitute the return pipe group 108G, a plurality of the waste solution pipes 122 constitute the waste solution pipe group 122G, and a plurality of the waste solution pipes 161 constitute the waste solution pipe group 161G (see FIG. 1).

The first solution flows into the supply pipe 106 from the supply pipe 102. The valve 106A is provided in the supply pipe 106, and adjusts a flow rate of the first solution flowing through the supply pipe 106 under control of the control unit 90.

The first solution flows into the return pipe 108 from the nozzle 106B. The first solution flowing through the return pipe 108 merges in the recovery pipe 110 and flows into the regeneration unit 7. The valve 108A is provided in the return pipe 108, and adjusts a flow rate of the first solution flowing through the return pipe 108 under control of the control unit 90.

The first waste solution flows into the waste solution pipe 122. The first waste solution flowing through the waste solution pipe group 122G merges in the recovery pipe 124 and flows into the regeneration unit 7. The valve 122A is provided in the waste solution pipe 122, and adjusts a flow rate of the first waste solution flowing through the waste solution pipe 122 under control of the control unit 90.

The second waste solution flows into the waste solution pipe 161. The second waste solution flowing through the waste solution pipe 161 merges in the discharged liquid pipe 160 and flows into the discharge unit 5. The valve 160A is provided in the waste solution pipe 161, and adjusts a flow rate of the second waste solution flowing through the waste solution pipe 161 under control of the control unit 90.

Hydrogen peroxide solution flows into the mixing pipe 200 from a hydrogen peroxide solution supply source 13 (see FIG. 1). The valve 200A is provided in the mixing pipe 200, and adjusts a flow rate of hydrogen peroxide solution flowing through the mixing pipe 200 under control of the control unit 90.

The nozzle 106B adds hydrogen peroxide solution to the first solution and supplies the first solution as treatment solution to the substrate W. The addition is not essential for substrate processing with the first solution. The addition increases temperature of the first solution in substrate processing. The temperature being high increases efficiency of substrate processing.

When temperature of the first solution before being used for substrate processing is high, peroxydisulfuric acid is easily decomposed as follows (symbol “.” indicates that peroxydisulfuric acid is a radical: the same applies hereinafter):

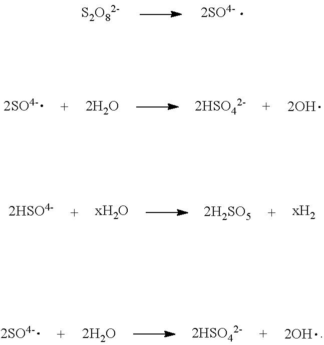

Such decomposition is also expressed as deactivation of peroxydisulfuric acid.

Suppressing deactivation without increasing temperature of the first solution until the first solution is used for substrate processing, and adding hydrogen peroxide solution to the first solution during the substrate processing contribute to increase in efficiency of the substrate processing.

The supply pipe 106, the return pipe 108, and the mixing pipe 200 are connected to the nozzle 106B. The first solution is supplied to the nozzle 106B from the supply pipe 102 by the supply pipe 106 via the valve 106A. Hydrogen peroxide solution is supplied from the hydrogen peroxide solution supply source 13 to the nozzle 106B through the valve 200A by the mixing pipe 200. The nozzle 106B causes the first solution, which is supplied from the supply pipe 106 but not used for treatment solution, to flow into the recovery pipe 110 by the return pipe 108 via the valve 108A.

For example, as will be described later, the nozzle 106B adds hydrogen peroxide solution to the first solution and dispenses the solution, or causes the first solution to flow into the return pipe 108 without adding hydrogen peroxide solution.

Although a case where the hydrogen peroxide solution supply source 13 is omitted in FIG. 3 and is provided outside the substrate processing apparatus 1 in FIG. 1 is exemplified, the hydrogen peroxide solution supply source 13 may be provided inside the substrate processing apparatus 1.

### <1-4. Processing Unit 600>

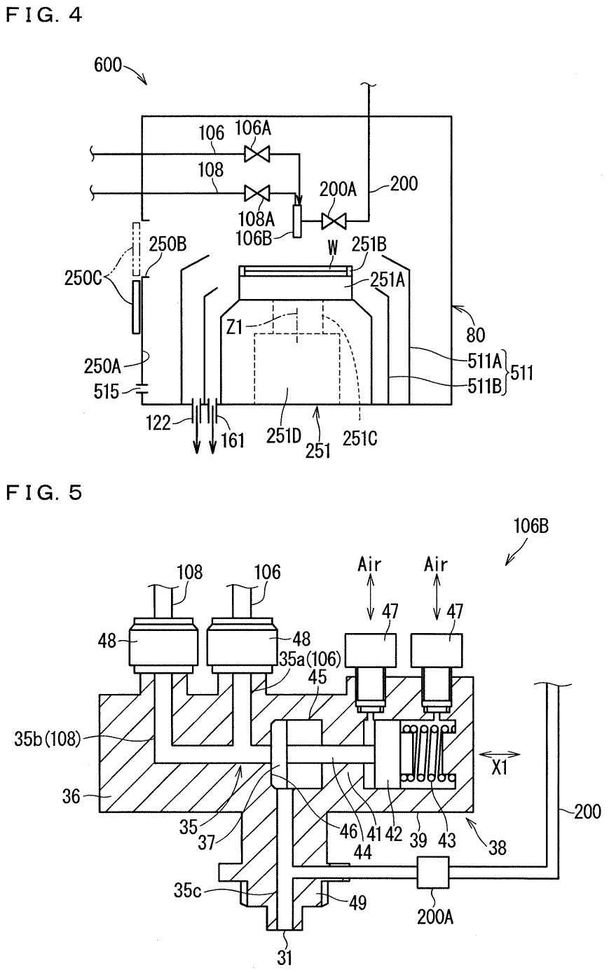

FIG. 4 is a schematic diagram schematically exemplifying the processing unit 600 and a related configuration. FIG. 4 illustrates an example of a configuration of the processing unit 600 arranged on the side (downstream side for the first solution flowing into the supply pipe 102; hereinafter, also simply referred to as “further on the downstream side than the supply pipe 102”) opposite to the supply pipes 102 of one of the supply pipes 106 exemplified in FIG. 3. The processing unit 600 arranged further on the downstream side than the supply pipe 102 of another one of the supply pipes 106 illustrated in FIG. 3 is also configured similarly to the configuration illustrated in FIG. 4.

The processing unit 600 includes a chamber 80, a spin chuck 251, and a processing cup 511.

The chamber 80 has a box shape with an internal space. The spin chuck 251 has a function of rotating one of the substrate W around a vertical rotation axis Z1 while holding the substrate W in a horizontal posture in the chamber 80. For example, the substrate W is held by the spin chuck 251 in a posture in which a central portion of the substrate W is located on the rotation axis Z1.

The nozzle 106B dispenses treatment solution toward a predetermined portion (for example, a spin base 251A) inside the chamber 80. The dispense when the substrate W is held by the spin base 251A corresponds to supply of treatment solution from the nozzle 106B to the substrate W.

A nozzle (for example, a nozzle for dispensing another chemical solution or a nozzle for dispensing rinse liquid) for dispensing solution for another use may be connected to the processing unit 600 separately from the nozzle 106B.

The processing cup 511 has an outer cup 511A and an inner cup 511B. Both the outer cup 511A and the inner cup 511B have a tubular shape extending along the rotation axis Z1.

The inner cup 511B surrounds the spin chuck 251, and the outer cup 511A surrounds the inner cup 511B.

The waste solution pipe 122 is provided at a bottom portion of the chamber 80 and inside the outer cup 511A and outside the inner cup 511B. The waste solution pipe 161 is provided at a bottom portion of the chamber 80, inside the inner cup 511B, and outside the spin chuck 251.

An upper end of the inner cup 511B is located below an upper end of the outer cup 511A. The outer cup 511A and the inner cup 511B are lifted or lowered in a vertical direction independently of or in conjunction with each other by a lifting mechanism (for example, a motor or a cylinder) (not illustrated).

When the substrate W is held by the spin chuck 251, upper ends of both the outer cup 511A and the inner cup 511B are also located further on the lower side than the spin base 251A. When the substrate W is subjected to substrate processing, an upper end of the outer cup 511A is located further on the upper side than the substrate W held by the spin chuck 251.

The inner cup 511B is movable to a position (hereinafter also provisionally referred to as “upper position”) further on the upper side than the substrate W held by the spin chuck 251 and further on the lower side than the outer cup 511A. The inner cup 511B is movable to a position (hereinafter, also provisionally referred to as “lower position”) further on the lower side than the substrate W held by the spin chuck 251 (position exemplified in FIG. 4).

When the first substrate processing is performed, the inner cup 511B is moved to the lower position. The first substrate processing is, for example, processing of removing resist on the substrate W with treatment solution. Since a peroxydisulfate ion functions for removal of resist, concentration of peroxydisulfate ions in the first solution contained in treatment solution is desirably high.

The first waste solution is received by an inner surface of the outer cup 511A. The first waste solution received by the outer cup 511A flows into the recovery pipe 124 via the waste solution pipe 122, is supplied to the regeneration unit 7, and is used for regeneration processing to be described later.

When the second substrate processing is performed, the inner cup 511B is moved to the upper position. The second substrate processing is, for example, rinse processing of rinsing the substrate W after the first substrate processing. Details of the rinse processing and description of the rinse solution for realizing the rinse processing and supply of the rinse solution to the substrate W are omitted in the present embodiment.

The second waste solution is received by an inner surface of the inner cup 511B. The second waste solution received by the inner cup 511B is not used for regeneration processing described later, but flows into the discharged liquid pipe 160 via the waste solution pipe 161 and is supplied to the discharge unit 5.

The chamber 80 has a box-shaped wall 250A. An opening portion 250B is formed in the wall 250A. Carrying-in of the substrate W into the chamber 80 and carrying-out of the substrate W from the chamber 80 are performed via the opening portion 250B.

The chamber 80 has a movable shutter 250C. The opening portion 250B is opened and closed by the shutter 250C. The shutter 250C is lifted or lowered between a closing position (indicated by a chain line in FIG. 4) at which the shutter 250C covers the opening portion 250B and an opening position (indicated by a solid line in FIG. 4) at which the shutter 250C opens the opening portion 250B by a shutter lifting mechanism (not illustrated).

The spin chuck 251 includes the spin base 251A, a plurality of chuck pins 251B, a rotation shaft 251C, and a spin motor 251D.

The spin base 251A has a disk shape. A plurality of the chuck pins 251B protrude upward from an outer peripheral portion of an upper surface of the spin base 251A. A plurality of the chuck pins 251B holds and releases a peripheral edge portion of the substrate W. The substrate W held by the chuck pin 251B faces the spin base 251A and is held in a horizontal posture in the spin chuck 251. The rotation shaft 251C extends downward from a central portion of the spin base 251A. The spin motor 251D rotates the rotation shaft 251C to rotate the substrate W in a state of being held by a plurality of the chuck pins 251B.

For example, instead of holding of the substrate W by a plurality of the chuck pins 251B, a vacuum suction type chuck having a spin base for vacuum suction of a lower surface of the substrate W may be employed as the spin chuck 251.

An exhaust port 515 is provided on a side portion of the chamber 80. Atmosphere in the chamber 80 is appropriately discharged to the outside of the chamber 80 through the exhaust port 515. Atmosphere in the processing cup 511 is exhausted by a cup exhaust mechanism (not illustrated).

### <1-5. Nozzle 106B>

FIG. 5 is a cross-sectional view exemplifying an internal structure of the nozzle 106B.

The nozzle 106B has a main body 36, a valve body 37, a pneumatic actuator 38, and a dispense port 31. The main body 36 has a valve chamber 45.

In the main body 36, a flow path 35 for guiding the first solution or treatment solution is formed. The valve body 37 opens and closes the flow path 35. The pneumatic actuator 38 moves the valve body 37 forward and backward in an axial direction X1 to open and close the flow path 35. The flow path 35 closer to the dispense port 31 side than the valve body 37 communicates with the mixing pipe 200. The flow path 35 closer to the dispense port 31 side than the mixing pipe 200 functions as a flow path 35c through which treatment solution flows. The flow path 35 farther from the dispense port 31 than the valve body 37 branches into flow paths 35a and 35b.

A pair of joints 48 are connected to the main body 36. The supply pipe 106 is connected to one of the joints 48, and the supply pipe 106 and the flow path 35a communicate with each other. The flow path 35a can also be regarded as a part of the supply pipe 106. The return pipe 108 is connected to the other one of the joints 48, and the return pipe 108 and the flow path 35b communicate with each other. The flow path 35b can also be regarded as a part of the return pipe 108.

The flow path 35a communicates with the supply pipe 106 and the valve chamber 45. The flow path 35b communicates with the return pipe 108 and the valve chamber 45. The flow path 35c communicates with the valve chamber 45 and the dispense port 31.

The pneumatic actuator 38 includes a cylinder 39, a piston 42, a spring 43, and a rod 44. The cylinder 39 and the valve chamber 45 are arranged along the axial direction X1. The cylinder 39 and the valve chamber 45 are separated from each other by a partition wall 41. The valve body 37 moves forward and backward in the valve chamber 45.

The cylinder 39 is separated by the piston 42 into a front chamber on the partition wall 41 side and a rear chamber that sandwiches the piston 42 together with the front chamber in the axial direction X1. The spring 43 is interposed between the piston 42 and the main body 36 on the rear chamber side of the cylinder 39. The spring 43 presses the piston 42 toward the partition wall 41.

A pair of joints 47 are connected to the main body 36. A tube (not illustrated) that transmits air pressure to the front chamber of the cylinder 39 is connected to one of the joints 47. A tube (not illustrated) that transmits air pressure to the rear chamber of the cylinder 39 is connected to the other one of the joints 47. As air pressure is transmitted to either the front chamber or the rear chamber of the cylinder 39 via these tubes and the joint 47, the piston 42 moves forward and backward in the cylinder 39 along the axial direction X1.

The rod 44 penetrates the partition wall 41 and extends along the axial direction X1. One end of the rod 44 is connected to the piston 42. Another end of the rod 44 is connected to the valve body 37. The valve body 37 has, for example, a disk shape, and its radial direction is orthogonal to the axial direction X1.

When the piston 42 moves forward and backward in the axial direction X1 in the cylinder 39, the valve body 37 moves forward and backward in the axial direction X1 in the valve chamber 45 by the rod 44.

The valve chamber 45 includes a valve seat surface 46. The valve seat surface 46 faces the partition wall 41 and has, for example, an annular shape orthogonal to the axial direction X1. The flow paths 35a and 35b are connected to, for example, an inner edge of an annular ring of the valve seat surface 46. When viewed along a moving forward and backward direction (axial direction X1) of the valve body 37, the flow path 35c is connected to a side of the valve chamber 45.

The main body 36 includes a cylindrical portion 49. The cylindrical portion 49 protrudes downward, and the dispense port 31 is formed at a tip on the lower side of the cylindrical portion 49. The mixing pipe 200 is introduced to a side of the cylindrical portion 49 and communicates with the flow path 35c.

When no air pressure is applied to either the front chamber or the rear chamber of the cylinder 39, the pneumatic actuator 38 is in a state of not operating. At this time, the piston 42 is pressed toward the valve chamber 45 side in the cylinder 39 by the spring 43, and the valve body 37 comes into contact with the valve seat surface 46 in the valve chamber 45. By the contact, the flow path 35 is closed between the flow paths 35a and 35b and the flow path 35c (a state exemplified in FIG. 5). At this time, the piston 42 is located close to the partition wall 41 side.

When the valves 106A and 108A are opened in this state, the first solution supplied from the supply tank 10 to the nozzle 106B through the supply pipe 106 and the flow path 35a is supplied to the regeneration unit 7 via the flow path 35b, the return pipe 108, and the recovery pipe 110. A state in which the first solution flows from the supply pipe 106 to the return pipe 108 without being used for substrate processing as described above is hereinafter referred to as “nozzle passing state”.

Even in the nozzle passing state, the first solution may flow from the supply pipe 102 to the regeneration unit 7 without being divided from the supply pipe 102 to the supply pipe 106.

In a situation where the nozzle passing state is obtained, as air pressure is transmitted to the front chamber of the cylinder 39, the piston 42 retracts in a rear chamber direction of the cylinder 39 against pressing force of the spring 43. At this time, the valve body 37 is separated from the valve seat surface 46 in the valve chamber 45. When the valve body 37 is separated from the valve seat surface 46, the flow paths 35a and 35c and the valve chamber 45 communicate with each other, the flow path 35c and the valve chamber 45 communicate with each other, and the flow paths 35a and 35c and the flow path 35c communicate with each other.

The first solution supplied from the supply tank 10 via the supply pipe 106 and the flow path 35a flows into the flow path 35c. At this time, when the valve 200A is opened, hydrogen peroxide solution is added from the mixing pipe 200 to the first solution in the flow path 35c. The first solution to which hydrogen peroxide solution is added is dispensed from the dispense port 31. A state in which treatment solution is dispensed from the dispense port 31 is hereinafter referred to as “dispense state”.

In a situation where the dispense state is obtained, by stopping transmission of air pressure to the front chamber of the cylinder 39 or by transmitting air pressure to the rear chamber of the cylinder 39 together with the stopping, the piston 42 moves forward in a front chamber direction of the cylinder 39 together with pressing force of the spring 43. At this time, the valve body 37 comes into contact with the valve seat surface 46 in the valve chamber 45. When the valve body 37 comes into contact with the valve seat surface 46, the flow paths 35a and 35b and the valve chamber 45 are blocked, the flow path 35c and the valve chamber 45 are blocked, and a flow path between the flow paths 35a and 35b and the flow path 35c is closed. In this way, the nozzle passing state is obtained.

When the nozzle 106B is in the dispense state (a state in which the valve body 37 in FIG. 5 is separated from the valve seat surface 46), the valve 106A is opened and the valve 108A is closed. The first solution is supplied to the flow path 35c. In the dispense state, the valve 200A is also opened, and hydrogen peroxide solution is also supplied from the mixing pipe 200 to the flow path 35c. In the flow path 35c, hydrogen peroxide solution is added to the first solution, and treatment solution is dispensed from the dispense port 31.

The nozzle 106B contributes to generation of treatment solution using the first solution. Treatment solution dispensed from the dispense port 31 reaches an upper surface of the substrate W, and substrate processing is performed.

As described above, flow of the first solution into the nozzle 106B in the supply pipe 106 not only in the dispensed state but also in the nozzle passing state suppresses temperature change of the first solution in the supply pipes 102 and 106, and thus contributes to suppression of temperature change of treatment solution used for substrate processing. For example, the first solution flowing through the supply pipe 102 and the nozzle 106B in the nozzle passing state is suppressed to a minimum flow rate to such an extent that temperature of the supply pipes 102 and 106 is maintained.

### <1-6. Discharge Unit 5>

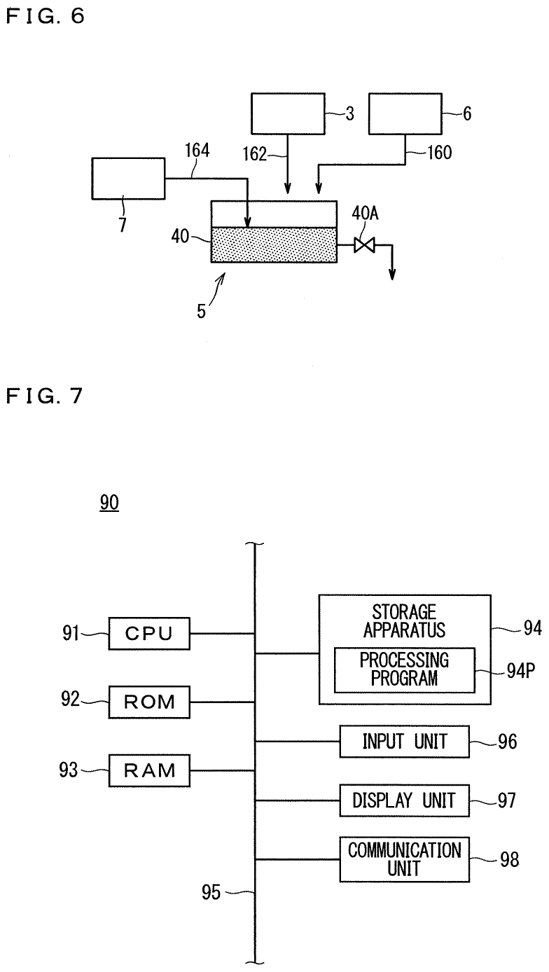

FIG. 6 is a schematic diagram exemplifying a configuration of the discharge unit 5. The discharge unit 5 has a function of discharging liquid unnecessary for the substrate processing apparatus 1 from the substrate processing apparatus 1. The discharge unit 5 includes a discharged liquid tank 40 and a valve 40A.

The first solution is supplied to the discharged liquid tank 40 from the supply and recovery unit 3, specifically, the supply tank 10 via the discharged liquid pipe 162. Any one or more than one of the first waste solution, and second solution, third solution, fourth solution, and fifth solution all of which will be described later, are supplied from the regeneration unit 7 to the discharged liquid tank 40 via a discharged liquid pipe 164. The second waste solution is supplied from the processing unit 6 to the discharged liquid tank 40 via the discharged liquid pipe 160.

The discharged liquid tank 40 stores any one or more than one of the first waste solution, the second waste solution, the first solution, the second solution, the third solution, the fourth solution, and the fifth solution. Liquid stored in the discharged liquid tank 40 is discharged to the outside of the substrate processing apparatus 1 via the valve 40A. The valve 40A adjusts a flow rate of liquid discharged from the discharged liquid tank 40 under control of the control unit 90.

### <1-7. Control Unit 90>

FIG. 7 is a block diagram conceptually exemplifying a configuration of the control unit 90. The control unit 90 may be configured by a general computer having an electric circuit. Specifically, the control unit 90 includes a central processing unit (that is, a CPU) 91, a read-only memory (that is, ROM) 92, a random access memory (that is, RAM) 93, a storage apparatus 94, an input unit 96, a display unit 97, a communication unit 98, and a bus line 95 connecting these units to each other.

The ROM 92 stores a basic program. The RAM 93 is used as a work area when the CPU 91 performs predetermined processing. The storage apparatus 94 includes a nonvolatile storage apparatus (for example, a flash memory or a hard disk apparatus). The input unit 96 includes, for example, various switches or a touch panel, and receives an input setting instruction (for example, a processing recipe) from an operator. The display unit 97 includes, for example, a liquid crystal display apparatus, a lamp, and the like, and displays various types of information under control of the CPU 91. The communication unit 98 has a data communication function via a local area network (LAN), for example.

In the storage apparatus 94, a plurality of modes for control of each configuration in the substrate processing apparatus 1 are set in advance. When the CPU 91 executes a processing program 94P, one of a plurality of the modes is selected, and each configuration is controlled in the mode. Note that the processing program 94P may be stored in a recording medium. By using this recording medium, the processing program 94P can be installed in the control unit 90. Further, some or all of functions executed by the control unit 90 are not necessarily realized by software, and may be realized by dedicated hardware, for example, a logic circuit.

### <2. Regeneration Unit 7>

The regeneration unit 7 performs regeneration processing. In the regeneration processing, first electrolysis and second electrolysis are performed in this order, and the first solution is generated by using the first waste solution.

### <2-1. First Embodiment of Regeneration Unit 7>

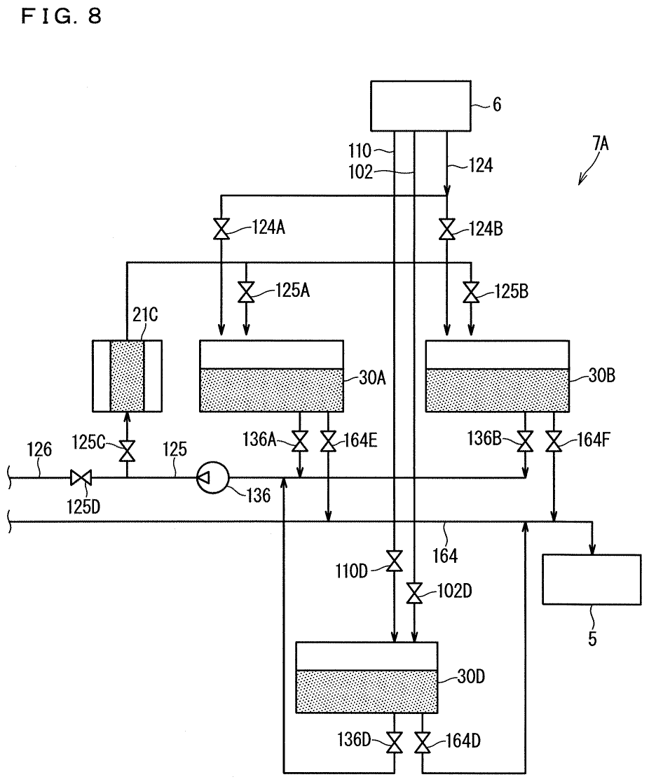

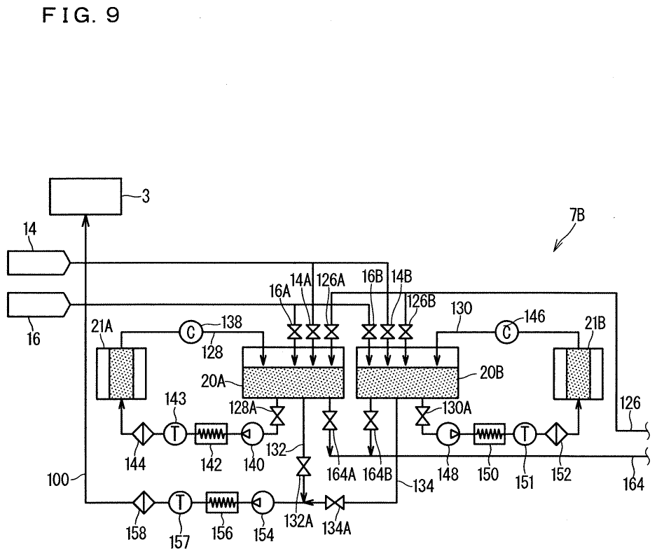

FIG. 8 is a schematic diagram exemplifying a configuration of a first recovery unit 7A. FIG. 9 is a schematic diagram exemplifying a configuration of a first sulfuric acid electrolysis unit 7B.

A first embodiment of the regeneration unit 7 includes the first recovery unit 7A, the first sulfuric acid electrolysis unit 7B, a recovery pipe 126, and the discharged liquid pipe 164. The recovery pipe 126 and the discharged liquid pipe 164 can be considered to be shared by the first recovery unit 7A and the first sulfuric acid electrolysis unit 7B, or can be considered to be included in either the first recovery unit 7A or the first sulfuric acid electrolysis unit 7B.

The first recovery unit 7A and the first sulfuric acid electrolysis unit 7B are connected by the recovery pipe 126 and the discharged liquid pipe 164.

### <2-1-1. First Recovery Unit 7A>

The first recovery unit 7A includes recovery tanks 30A, 30B, and 30D, valves 102D, 110D, 124A, 124B, 125A, 125B, 125C, 125D, 136A, 136B, 136D, 164D, 164E, and 164F, a circulation pipe 125, a pump 136, and an electrolysis cell 21C.

The recovery pipe 124 supplies the first waste solution to the recovery tank 30A via the valve 124A, and supplies the first waste solution to the recovery tank 30B via the valve 124B. Each of the recovery tanks 30A and 30B functions as a second tank that stores the second solution. The second solution is a provisional term including either or both of the first waste solution and the third solution described later.

The valve 124A adjusts a flow rate of the first waste solution to be supplied to the recovery tank 30A, and the valve 124B adjusts a flow rate of the first waste solution to be supplied to the recovery tank 30B under control of the control unit 90.

The valve 164E is provided between the recovery tank 30A and the discharged liquid pipe 164. The valve 164E adjusts an amount of the second solution supplied from the recovery tank 30A to the discharge unit 5 via the discharged liquid pipe 164.

The valve 164F is provided between the recovery tank 30B and the discharged liquid pipe 164. The valve 164F adjusts an amount of the second solution supplied from the recovery tank 30B to the discharge unit 5 via the discharged liquid pipe 164.

A flow rate is adjusted by the valves 164E and 164F under control of the control unit 90.

The recovery tank 30A supplies the second solution to the pump 136 via the valve 136A, and the recovery tank 30B supplies the second solution to the pump 136 via the valve 136B.

Both the valves 136A and 136B adjust a flow rate of the second solution to be supplied to the pump 136 under control of the control unit 90.

The second solution stored in the recovery tank 30A is fed via the valve 136A, and the second solution stored in the recovery tank 30B is fed via the valve 136B, and both of the second solutions are fed through either or both of the circulation pipe 125 and the recovery pipe 126 by the pump 136.

The first recovery unit 7A decomposes an organic substance contained in the first waste solution by electrolysis performed by the electrolysis cell 21C. The third solution is generated from the first waste solution by the electrolysis. It can also be said that electrolysis is performed on the second solution to generate the third solution. Electrolysis that decomposes an organic substance as described above is the first electrolysis.

The recovery pipe 110 supplies the first solution to the recovery tank 30D via the valve 110D, and the supply pipe 102 supplies the first solution to the recovery tank 30D via the valve 102D. The recovery tank 30D contributes to cooling of the first solution.

The valves 102D and 110D adjust a flow rate of the first solution to be supplied to the recovery tank 30D under control of the control unit 90.

The valve 164D is provided between the recovery tank 30D and the discharged liquid pipe 164. The valve 164D adjusts an amount of the first solution supplied from the recovery tank 30D to the discharge unit 5 via the discharged liquid pipe 164. The recovery tank 30D supplies the first solution to the pump 136 via the valve 136D. A flow rate is adjusted by the valves 136D and 164D under control of the control unit 90.

The valve 125D adjusts a flow rate of the fourth solution flowing from the circulation pipe 125 to the recovery pipe 126 under control of the control unit 90. The fourth solution is a provisional term that refers to either or both of the first solution and the third solution.

Before the first electrolysis is performed using the recovery tank 30A, an amount of the first waste solution suitable for the first electrolysis is stored in the recovery tank 30A by adjustment of the valves 124A and 164E.

Before the first electrolysis is performed using the recovery tank 30B, an amount of the first waste solution suitable for the first electrolysis is stored in the recovery tank 30B by adjustment of the valves 124B and 164F.

The valve 125D is closed both in a case where the first electrolysis is performed using the recovery tank 30A and in a case where the first electrolysis is performed using the recovery tank 30B. An amount of the organic substance contained in the first solution is small, the first electrolysis does not need to be performed on the first solution, and the valve 136D is closed.

When the first electrolysis is performed using the recovery tank 30A, the valves 124A and 164E close and the valves 125A, 136A, and 125C open. Due to solution feeding by the pump 136, the third solution circulates in the circulation pipe 125 between the recovery tank 30A and the electrolysis cell 21C, and the first electrolysis is performed in the electrolysis cell 21C.

When the first electrolysis is performed using the recovery tank 30B, the valves 124B and 164F close and the valves 125B, 136B, and 125C open. Due to solution feeding by the pump 136, the third solution circulates in the circulation pipe 125 between the recovery tank 30B and the electrolysis cell 21C, and the first electrolysis is performed in the electrolysis cell 21C.

It is not desirable that temperature of the second solution is high in the first electrolysis. The recovery tanks 30A and 30B store the second solution and lower temperature of the second solution to, for example, 60° C. or less. Performing supply of the first waste solution to the recovery tanks 30A and 30B and the first electrolysis using the recovery tanks 30A and 30B in a complementary manner contributes to efficiency improvement of the first electrolysis as compared with a case where only one of the recovery tanks 30A and 30B is employed for the first electrolysis.

For example, when the valve 124A is open, the valve 136A is closed and the first waste solution is supplied to the recovery tank 30A, and the valves 125B and 136B are opened and the first electrolysis using the recovery tank 30B is performed. For example, when the valve 124B is open, the valve 136B is closed and the first waste solution is supplied to the recovery tank 30B, and the valves 125A and 136A are opened and the first electrolysis using the recovery tank 30A is performed.

In the first electrolysis, an organic substance is decomposed as follows:

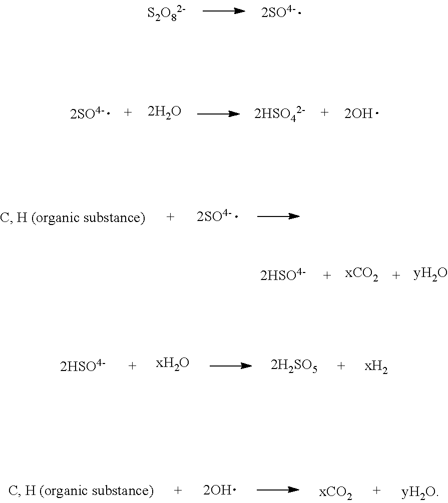

The longer the time during which the first electrolysis is executed, the more an organic substance is decomposed. For example, the first electrolysis is executed for a period during which an organic substance is assumed to be decomposed to desired degree.

Upon completion of the first electrolysis, both the valves 125A and 125B or the valve 125C closes. Upon completion of the first electrolysis, either or both of the valves 136A, 136B open. Upon completion of the first electrolysis, the valve 136D opens.

The third solution supplied from the recovery tank 30A via the valves 136A and 125D, the third solution supplied from the recovery tank 30B via the valves 136B and 125D, and the first solution supplied from a recovery tank 30C via the valve 136D are supplied to the recovery pipe 126 by the pump 136.

The path for performing the first electrolysis on the second solution to generate the third solution is hereinafter also provisionally referred to as a “first path”. For example, the valves 125A, 136A, and 125C, the electrolysis cell 21C, and the circulation pipe 125 are considered as the first path through which the second solution circulates to and from the recovery tank 30A. For example, the valves 125B, 136B, and 125C, the electrolysis cell 21C, and the circulation pipe 125 are considered as the first path through which the second solution circulates to and from the recovery tank 30B.

In the first recovery unit 7A, the recovery tank 30A and the first path relating to the recovery tank 30A may be provided, and the recovery tank 30B and the first path relating to the recovery tank 30B may be omitted.

### <2-1-2. First Sulfuric Acid Electrolysis Unit 7B>

The first sulfuric acid electrolysis unit 7B includes regeneration tanks 20A and 20B, electrolysis cells 21A and 21B, circulation pipes 128 and 130, supply pipes 132 and 134, and valves 126A and 126B.

The fourth solution is supplied from the recovery pipe 126 to the regeneration tank 20A via the valve 126A, and to the regeneration tank 20B via the valve 126B. Both the valves 126A and 126B adjust a flow rate of the supplied fourth solution under control of the control unit 90. The fourth solution is a provisional term that refers to either or both of the first solution and the third solution. It can be said that both the regeneration tanks 20A and 20B store the fourth solution.

Both the regeneration tanks 20A and 20B function as third tanks that store the third solution.

The circulation pipe 128 circulates the fourth solution between the regeneration tank 20A and the electrolysis cell 21A. In the circulation, the electrolysis cell 21A performs electrolysis on the third solution contained in the fourth solution to generate the first solution. The circulation pipe 130 circulates the fourth solution stored in the regeneration tank 20B. In the circulation, the electrolysis cell 21B performs electrolysis on the third solution contained in the fourth solution to generate the first solution. These electrolysis operations are the second electrolysis described above.

In the second electrolysis, a peroxydisulfate ion is generated as follows:

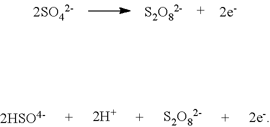

Both the regeneration tanks 20A and 20B store the first solution obtained by the second electrolysis and the first solution that was stored in the recovery tank 30D.

The supply pipe 132 supplies the first solution to the supply pipe 100 from the regeneration tank 20A, and the supply pipe 134 supplies the first solution to the supply pipe 100 from the regeneration tank 20B.

The circulation pipe 128 is provided with a valve 128A, a pump 140, a heater 142, a thermometer 143, a filter 144, the electrolysis cell 21A, and a concentration meter 138.

The valve 128A adjusts a flow rate of the fourth solution flowing from the regeneration tank 20A to the circulation pipe 128 under control of the control unit 90.

The pump 140 feeds the fourth solution flowing through the circulation pipe 128. The heater 142 heats the fourth solution flowing through the circulation pipe 128. The thermometer 143 measures temperature of the fourth solution flowing through the circulation pipe 128. The filter 144 removes a foreign substance, for example, a particle, in the fourth solution flowing through the circulation pipe 128. The concentration meter 138 measures sulfuric acid concentration of the fourth solution flowing through the circulation pipe 128.

The circulation pipe 130 is provided with a valve 130A, a pump 148, a heater 150, a thermometer 151, a filter 152, the electrolysis cell 21B, and a concentration meter 146.

The valve 130A adjusts a flow rate of the fourth solution flowing from the regeneration tank 20B to the circulation pipe 130 under control of the control unit 90.

The pump 148 feeds the fourth solution flowing to the circulation pipe 130. The heater 150 heats the fourth solution flowing through the circulation pipe 130. The thermometer 151 measures temperature of the fourth solution flowing through the circulation pipe 130. The filter 152 removes a foreign substance, for example, a particle, in the fourth solution flowing through the circulation pipe 130. The concentration meter 146 measures sulfuric acid concentration of the fourth solution flowing through the circulation pipe 130.

The “sulfuric acid concentration” includes all of concentration of sulfuric acid, concentration of peroxymonosulfuric acid, and concentration of peroxydisulfuric acid. For example, the fact that concentration of peroxydisulfuric acid is higher than a desired lower limit is estimated based on the time during which the second electrolysis is performed. The second electrolysis is terminated when the time during which the second electrolysis is executed exceeds predetermined time.

In the first sulfuric acid electrolysis unit 7B, the supply pipe 100 is provided with a pump 154, a heater 156, a thermometer 157, and a filter 158.

The first solution is supplied to the pump 154 from the regeneration tank 20A via the supply pipe 132 and a valve 132A, and from the regeneration tank 20B via the supply pipe 134 and a valve 134A. The pump 154 feeds the first solution flowing through the supply pipe 100.

The valve 132A adjusts a flow rate of the first solution flowing through the supply pipe 132, and the valve 134A adjusts a flow rate of the first solution flowing through the supply pipe 134 under control of the control unit 90.

The filter 158 removes a foreign substance, for example, a particle, in the first solution flowing through the supply pipe 100.

The thermometer 157 measures temperature of the first solution flowing through the supply pipe 100. The heater 156 heats the first solution so that temperature measured by the thermometer 157 is, for example, 90° C. Such temperature adjustment is performed under control of the control unit 90.

The first sulfuric acid electrolysis unit 7B has valves 164A and 164B. The regeneration tank 20A supplies the fourth solution to the discharged liquid pipe 164 via the valve 164A, and the regeneration tank 20B supplies the fourth solution to the discharged liquid pipe 164 via the valve 164B. A flow rate is adjusted by the valves 164A and 164B under control of the control unit 90.

Pure water (DIW), hydrogen peroxide solution, or ozone water is supplied from a pure water supply source 14 to the regeneration tank 20A and the regeneration tank 20B. A flow rate of pure water or the like supplied from the pure water supply source 14 to the regeneration tank 20A can be adjusted by control of a valve 14A by the control unit 90. Further, a flow rate of pure water or the like supplied from the pure water supply source 14 to the regeneration tank 20B can be adjusted by control of a valve 14B by the control unit 90.

The regeneration tank 20A and the regeneration tank 20B are supplied with sulfuric acid from a sulfuric acid supply source 16. A flow rate of sulfuric acid supplied from the sulfuric acid supply source 16 to the regeneration tank 20A can be adjusted by control of a valve 16A by the control unit 90. Further, a flow rate of sulfuric acid supplied from the sulfuric acid supply source 16 to the regeneration tank 20B can be adjusted by control of a valve 16B by the control unit 90.

In order to simplify explanation, first, a case where the second electrolysis is performed using the regeneration tank 20A will be described. Prior to the second electrolysis, an amount of the fourth solution suitable for the second electrolysis is stored in the regeneration tank 20A by adjustment of the valves 126A and 164A.

In the second electrolysis, the valve 132A is closed, and the regeneration tank 20A and the supply pipe 100 do not communicate with each other. The valve 164A is closed, and the regeneration tank 20A and the discharged liquid pipe 164 do not communicate with each other. The valve 126A is closed, and the fourth solution is not supplied from the recovery pipe 126 to the regeneration tank 20A.

In the second electrolysis, the valve 128A is opened, the pump 140 operates, and the fourth solution stored in the regeneration tank 20A is supplied to the electrolysis cell 21A. The electrolysis cell 21A functions as an electrolyzer. The electrolysis cell 21A operates to cause the third solution contained in the fourth solution to undergo the second electrolysis to generate the first solution which is supplied to the regeneration tank 20A. In this manner, the proportion of the first solution increases in the fourth solution stored in the regeneration tank 20A.

In a case where the second electrolysis is performed in the regeneration tank 20A, the fourth solution may be supplied to the regeneration tank 20B via the valve 126B, or the fourth solution may be discharged from the regeneration tank 20B via the valve 164B. For example, in these processing steps, the valve 130A is closed.

When sulfuric acid concentration measured by the concentration meter 138 is low, for example, the valve 16A is opened, and sulfuric acid is supplied to the regeneration tank 20A. When sulfuric acid concentration measured by the concentration meter 138 is high, for example, the valve 14A is opened, and pure water, hydrogen peroxide solution, or ozone water is supplied to the regeneration tank 20A.

For example, when measured sulfuric acid concentration falls within a predetermined range continuously in a period required for the entire fourth solution stored in the regeneration tank 20A to flow through the electrolysis cell 21A, the measured sulfuric acid concentration can be considered to be sulfuric acid concentration of the fourth solution stored in the regeneration tank 20A.

Also in the regeneration tank 20B, the second electrolysis using the circulation pipe 130, the pump 148, the heater 150, the thermometer 151, and the filter 152 is performed. At this time, the valve 134A is closed, and the regeneration tank 20B and the supply pipe 100 do not communicate with each other. The valve 164B is closed, and the regeneration tank 20B and the discharged liquid pipe 164 do not communicate with each other. The valve 126B is closed, and the fourth solution is not supplied from the recovery pipe 126 to the regeneration tank 20B.

In the second electrolysis, the valve 130A is opened, the pump 148 operates, and the fourth solution stored in the regeneration tank 20B is supplied to the electrolysis cell 21B. The electrolysis cell 21B functions as an electrolyzer. The electrolysis cell 21B operates to cause the third solution contained in the fourth solution to undergo the second electrolysis to generate the first solution which is supplied to the regeneration tank 20B. In this manner, the proportion of the first solution increases in the fourth solution stored in the regeneration tank 20B.

In a case where the second electrolysis is performed in the regeneration tank 20B, the fourth solution may be supplied to the regeneration tank 20A via the valve 126A, or the fourth solution may be discharged from the regeneration tank 20A via the valve 164A. For example, in these processing steps, the valve 128A is closed.

When sulfuric acid concentration measured by the concentration meter 146 is low, for example, the valve 16B is opened, and sulfuric acid is supplied to the regeneration tank 20B. When sulfuric acid concentration measured by the concentration meter 146 is high, for example, the valve 14B is opened, and pure water, hydrogen peroxide solution, or ozone water is supplied to the regeneration tank 20B.

For example, when measured sulfuric acid concentration falls within a predetermined range continuously in a period required for the entire fourth solution stored in the regeneration tank 20B to flow through the electrolysis cell 21B, the measured sulfuric acid concentration can be considered to be sulfuric acid concentration of the fourth solution stored in the regeneration tank 20B.

For example, the second electrolysis is executed at higher temperature than the first electrolysis. For example, temperature of the fourth solution in the second electrolysis is higher than temperature of the second solution in the first electrolysis. For example, before the first electrolysis is executed in the first recovery unit 7A, the second solution is cooled to room temperature in the recovery tanks 30A and 30B. For example, temperature of the fourth solution in the second electrolysis is increased to 60° C.

Such temperature increase is performed by the heater 142 by utilizing temperature measurement by the thermometer 143, for example, or by the heater 150 by utilizing temperature measurement by the thermometer 151, for example, under control of the control unit 90.

That either or both of supply and discharge of the fourth solution using the regeneration tank 20B are performed while the second electrolysis using the regeneration tank 20A is performed, and either or both of supply and discharge of the fourth solution using the regeneration tank 20A are performed while the second electrolysis using the regeneration tank 20B is performed contributes to efficiency improvement of the second electrolysis.

The second electrolysis using the regeneration tank 20A and the second electrolysis using the regeneration tank 20B may be performed in parallel.

The path for performing the second electrolysis on the third solution to generate the first solution is hereinafter also provisionally referred to as a “second path”. For example, the valve 128A, the filter 144, the electrolysis cell 21A, and the circulation pipe 128 are considered as the second path for generating the first solution while filtering the third solution by the filter 144. For example, the valve 130A, the filter 152, the electrolysis cell 21B, and the circulation pipe 130 are considered as the second path for generating the first solution while filtering the third solution by the filter 152.

The supply pipes 100, 132, and 134 are considered as a third path for supplying the first solution from the regeneration unit 7, more specifically, the first sulfuric acid electrolysis unit 7B, to the supply tank 10.

From the above operation, it can be said that the first solution is generated using the first waste solution in the regeneration processing, and the first electrolysis and the second electrolysis are performed in this order. In the first electrolysis, an organic substance contained in the first waste solution is decomposed. Therefore, when a peroxydisulfate ion is generated in the second electrolysis, an organic substance flowing through the circulation pipes 128 and 130 is reduced, and life of the filters 144 and 152 is extended.

For example, referring also to FIG. 8, during the second electrolysis or after the second electrolysis is completed, the valves 136D, 125D, and 126A are opened in a state where the valves 136A and 136B are closed, and the first solution is supplied from the recovery tank 30D to the regeneration tank 20A.

For example, referring also to FIG. 8, during the second electrolysis or after the second electrolysis is completed, the valves 136D, 125D, and 126B are opened in a state where the valves 136A and 136B are closed, and the first solution is supplied from the recovery tank 30D to the regeneration tank 20B.

The regeneration tank 20A and the second path relating to the regeneration tank 20A may be provided in the first sulfuric acid electrolysis unit 7B, and the regeneration tank 20B and the second path relating to the regeneration tank 20B may be omitted.

### 2-2. Second Embodiment of Regeneration Unit 7

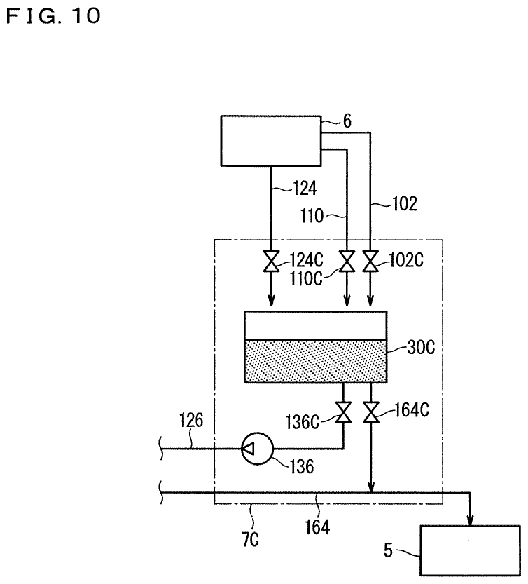

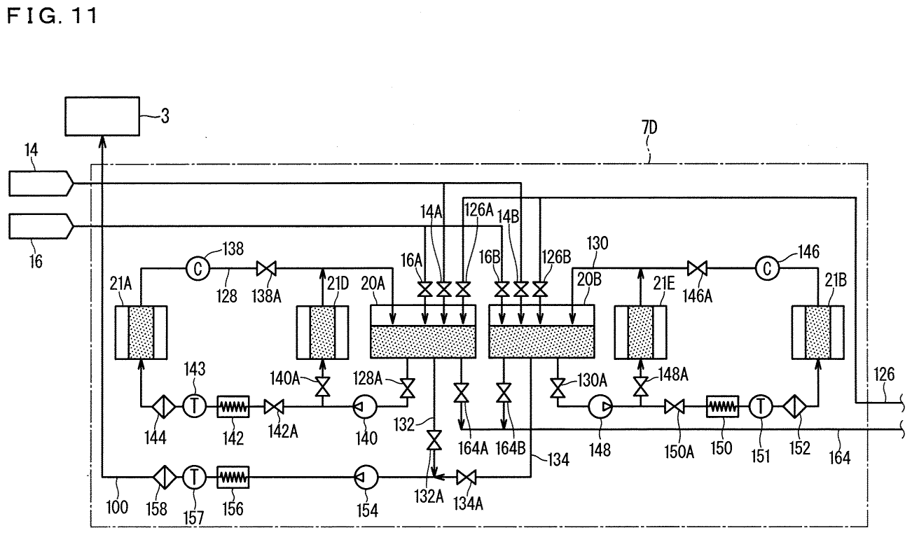

FIG. 10 is a schematic diagram exemplifying a configuration of a second recovery unit 7C. FIG. 11 is a schematic diagram exemplifying a configuration of a second sulfuric acid electrolysis unit 7D.

A second embodiment of the regeneration unit 7 includes the second recovery unit 7C, the second sulfuric acid electrolysis unit 7D, the recovery pipe 126, and the discharged liquid pipe 164. The recovery pipe 126 and the discharged liquid pipe 164 can be considered to be shared by the second recovery unit 7C and the second sulfuric acid electrolysis unit 7D, or can be considered to be included in either the second recovery unit 7C or the second sulfuric acid electrolysis unit 7D.

The second recovery unit 7C and the second sulfuric acid electrolysis unit 7D are connected by the recovery pipe 126 and the discharged liquid pipe 164.

### <2-2-1. Second Recovery Unit 7C>

The second recovery unit 7C includes a recovery tank 30C, valves 124C, 136C, 164C, 110C, and 102C, and the pump 136.

Unlike the first recovery unit 7A, the second recovery unit 7C does not perform the first electrolysis. In the regeneration processing, specifically, both the first electrolysis and the second electrolysis are performed in the second sulfuric acid electrolysis unit 7D.

The recovery pipe 124 supplies the first waste solution to the recovery tank 30C via the valve 124C. The valve 124C adjusts a flow rate of the first waste solution to be supplied to the recovery tank 30C under control of the control unit 90.

By adjustment of the valve 124C, an amount of the first waste solution suitable for the regeneration processing in the second sulfuric acid electrolysis unit 7D is supplied to the recovery tank 30C.

Under control of the control unit 90, the supply pipe 102 adjusts a flow rate of the first solution to be supplied to the recovery tank 30C via the valve 102C, and the recovery pipe 110 adjusts a flow rate of the first solution to be supplied to the recovery tank 30C via the valve 110C.

The recovery tank 30C stores the fifth solution. The fifth solution is a mixture of the first waste solution and the first solution.

The valve 164C is provided between the recovery tank 30C and the discharged liquid pipe 164. The valve 164C adjusts an amount of the fifth solution supplied from the recovery tank 30C to the discharge unit 5 via the discharged liquid pipe 164. A flow rate is adjusted by the valve 164C under control of the control unit 90.

The recovery tank 30C supplies the fifth solution to the pump 136 via the valve 136C. The valve 136C adjusts a flow rate of the fifth solution to be supplied to the pump 136 under control of the control unit 90.

By adjustment of the valve 136C and operation of the pump 136, the fifth solution supplied to the second sulfuric acid electrolysis unit 7D flows to the recovery pipe 126.

It is not desirable that temperature of the first solution is high in the first electrolysis. The recovery tank 30C stores the fifth solution and lower temperature of the fifth solution to, for example, 60° C. or less. The recovery tank 30C storing the fifth solution before being sent to the second sulfuric acid electrolysis unit 7D contributes to efficiency improvement of the first electrolysis in the second sulfuric acid electrolysis unit 7D.

### <2-2-2. Second Sulfuric Acid Electrolysis Unit 7D>

The second sulfuric acid electrolysis unit 7D has a configuration in which electrolysis cells 21D and 21E and valves 138A, 140A, 142A, 146A, 148A, and 150A are added to the first sulfuric acid electrolysis unit 7B (see FIG. 9).

For example, all of the valves 138A, 140A, 142A, 146A, 148A, and 150A are on-off valves, and opening and closing of these are controlled by the control unit 90.

The valves 138A and 142A are provided in the circulation pipe 128. The valve 138A separates the heater 142, the thermometer 143, the filter 144, the electrolysis cell 21A, and the concentration meter 138 from the liquid surface side of the regeneration tank 20A in the circulation pipe 128. The valve 142A separates the heater 142, the thermometer 143, the filter 144, the electrolysis cell 21A, and the concentration meter 138 from the pump 140 and the valve 128A in the circulation pipe 128.

The circulation pipe 128 branches between the liquid surface side of the regeneration tank 20A and the valve 138A, and the electrolysis cell 21D is provided at the branch. The circulation pipe 128 branches between the pump 140 and the valve 142A, and the valve 140A is provided at the branch. The valve 140A and the electrolysis cell 21D are connected in series between the valves 138A and 142A. The order of connection of the valve 140A and the electrolysis cell 21D may be reversed.

The valves 146A and 150A are provided in the circulation pipe 130. The valve 146A separates the heater 150, the thermometer 151, the filter 152, the electrolysis cell 21B, and the concentration meter 146 from the liquid surface side of the regeneration tank 20B in the circulation pipe 130. The valve 150A separates the heater 150, the thermometer 151, the filter 152, the electrolysis cell 21B, and the concentration meter 146 from the pump 148 and the valve 130A in the circulation pipe 130.

The circulation pipe 130 branches between the liquid surface side of the regeneration tank 20B and the valve 146A, and the electrolysis cell 21E is provided at the branch. The circulation pipe 130 branches between the pump 148 and the valve 150A, and the valve 148A is provided at the branch. The valve 148A and the electrolysis cell 21E are connected in series between the valves 146A and 150A. The order of connection of the valve 148A and the electrolysis cell 21E may be reversed.

The fifth solution is supplied from the recovery pipe 126 to the regeneration tank 20A via the valve 126A, and to the regeneration tank 20B via the valve 126B. Both the valves 126A and 126B adjust a flow rate of the supplied fifth solution under control of the control unit 90.

In the regeneration tank 20A, the fifth solution is stored until the first electrolysis is started. In the regeneration tank 20A, since the third solution is generated from the first waste solution in the fifth solution in the first electrolysis, it can be said that the fifth solution and the third solution are stored, or the first solution and the second solution are included. In the regeneration tank 20A, the second electrolysis generates the first solution from the third solution. From these viewpoints, it can be said that the regeneration tank 20A is a second tank that stores the second solution or a third tank that stores the third solution. Similarly, it can be said that the regeneration tank 20B is a second tank or a third tank.

In the second sulfuric acid electrolysis unit 7D, the pump 140 and the electrolysis cell 21D are operated in a state where the valves 128A and 140A are opened and the valves 138A and 142A are closed, and the first electrolysis is performed on the first waste solution contained in the fifth solution stored in the regeneration tank 20A.

Since the fifth solution stored in the regeneration tank 20A is blocked by the valves 138A and 142A, the fifth solution is fed by operation of the pump 140 in the circulation pipe 128 via the valves 128A and 140A without passing through the electrolysis cell 21A and the filter 144. The first waste solution contained in the fifth solution undergoes the first electrolysis by the electrolysis cell 21D. As the first electrolysis progresses, an amount of the first waste solution in the regeneration tank 20A decreases, and an amount of the third solution increases.

The first electrolysis using the regeneration tank 20A is completed, for example, based on lapse of time, similarly to the first electrolysis in the first recovery unit 7A. At a time point at which the first electrolysis is completed, the regeneration tank 20A substantially stores the fourth solution.

After the first electrolysis is completed, the valves 128A, 138A, and 142A are opened, and the pump 140 and the electrolysis cell 21A are operated in a state where the valve 140A is closed, so that the second electrolysis is performed on the third solution contained in the fourth solution stored in the regeneration tank 20A.

Since the fourth solution stored in the regeneration tank 20A is blocked by the valve 140A, the fourth solution is fed by operation of the pump 140 in the circulation pipe 128 via the valves 128A, 138A, and 142A without passing through the electrolysis cell 21D. While the fourth solution is filtered by the filter 144, the third solution contained in the fourth solution undergoes the second electrolysis by the electrolysis cell 21A. As the second electrolysis progresses, an amount of the third solution in the regeneration tank 20A decreases and an amount of the first solution increases.

The second electrolysis using the regeneration tank 20A is completed, for example, based on lapse of time, similarly to the second electrolysis in the first sulfuric acid electrolysis unit 7B. At a time point at which the second electrolysis is completed, the regeneration tank 20A substantially stores the first solution.

From such operation, it can be said that the electrolysis cell 21D is a first electrolyzer that performs the first electrolysis. It can be said that the electrolysis cell 21A is a second electrolyzer that performs the second electrolysis.

In the second sulfuric acid electrolysis unit 7D, the pump 148 and the electrolysis cell 21E are operated in a state where the valves 130A and 148A are opened and the valves 146A and 150A are closed, and the first electrolysis is performed on the first waste solution contained in the fifth solution stored in the regeneration tank 20B.

Since the fifth solution stored in the regeneration tank 20B is blocked by the valves 146A and 150A, the fifth solution is fed by operation of the pump 148 in the circulation pipe 130 via the valves 130A and 148A without passing through the electrolysis cell 21E and the filter 152. The first waste solution contained in the fifth solution undergoes the first electrolysis by the electrolysis cell 21E. As the first electrolysis progresses, an amount of the first waste solution in the regeneration tank 20B decreases, and an amount of the third solution increases.

The first electrolysis using the regeneration tank 20B is completed, for example, based on lapse of time, similarly to the first electrolysis in the first recovery unit 7A. At a time point at which the first electrolysis is completed, the regeneration tank 20B substantially stores the fourth solution.

After the first electrolysis is completed, the valves 130A, 146A, and 150A are opened, and the pump 148 and the electrolysis cell 21B are operated in a state where the valve 148A is closed to perform the second electrolysis on the third solution contained in the fourth solution stored in the regeneration tank 20B.

Since the fourth solution stored in the regeneration tank 20B is blocked by the valve 148A, the fourth solution is fed by operation of the pump 148 in the circulation pipe 130 via the valves 130A, 146A, and 150A without passing through the electrolysis cell 21E. While the fourth solution is filtered by the filter 152, the third solution contained in the fourth solution undergoes the second electrolysis by the electrolysis cell 21B. As the second electrolysis progresses, an amount of the third solution in the regeneration tank 20B decreases and an amount of the first solution increases.

The second electrolysis using the regeneration tank 20B is completed, for example, based on lapse of time, similarly to the second electrolysis in the first sulfuric acid electrolysis unit 7B. At a time point at which the second electrolysis is completed, the regeneration tank 20B substantially stores the first solution.

From such operation, it can be said that the electrolysis cell 21E is the first electrolyzer that performs the first electrolysis. It can be said that the electrolysis cell 21B is the second electrolyzer that performs the second electrolysis.

Operation of the second sulfuric acid electrolysis unit 7D other than the first electrolysis by the electrolysis cells 21D and 21E is similar to operation of the first sulfuric acid electrolysis unit 7B.

The first electrolysis using the regeneration tank 20A and the first electrolysis using the regeneration tank 20B may be performed in parallel. The second electrolysis using the regeneration tank 20A and the second electrolysis using the regeneration tank 20B may be performed in parallel.

The second electrolysis using the regeneration tank 20B may be performed while the first electrolysis using the regeneration tank 20A is performed. The first electrolysis using the regeneration tank 20B may be performed while the second electrolysis using the regeneration tank 20A is performed. Performing the first electrolysis and the second electrolysis in a complementary manner by the regeneration tanks 20A and 20B contributes to efficiency improvement of the regeneration processing more than a case where only one of the regeneration tanks 20A and 20B is employed in the second sulfuric acid electrolysis unit 7D.

In the second embodiment, for example, the valves 128A and 140A, the electrolysis cell 21D, and the circulation pipe 128 are considered as the first path through which the second solution circulates to and from the regeneration tank 20A. For example, the valves 130A and 148A, the electrolysis cell 21E, and the circulation pipe 130 are considered as the first path through which the second solution circulates to and from the regeneration tank 20B.

Also in the second embodiment, similarly to the first embodiment, for example, the valve 128A, the filter 144, the electrolysis cell 21A, and the circulation pipe 128 are considered as the second path for generating the first solution while filtering the third solution by the filter 144. For example, the valve 130A, the filter 152, the electrolysis cell 21B, and the circulation pipe 130 are considered as the second path for generating the first solution while filtering the third solution by the filter 152.

Also in the second embodiment, similarly to the first embodiment, the supply pipes 100, 132, and 134 are considered as the third path for supplying the first solution from the regeneration unit 7, more specifically, the second sulfuric acid electrolysis unit 7D to the supply tank 10.

Also in the second embodiment, life of the filters 144 and 152 is extended similarly to the first embodiment.

Also in the second embodiment, similarly to the first embodiment, the electrolysis cells 21A and 21B do not perform the first electrolysis, so that deterioration of the electrolysis cells 21A and 21B is suppressed.

In the first embodiment, the valve 136D, the valve 136A, and the valve 136B can be exclusively opened and closed (see FIG. 8). The first embodiment has an advantage over the second embodiment from the viewpoint that regeneration processing can be made unnecessary for the first solution supplied from the recovery pipe 110 and the supply pipe 102 to the regeneration unit 7 by the opening and closing.

Also in the second embodiment, as in the first embodiment, for example, the second electrolysis is performed at higher temperature than the first electrolysis. Such temperature control can be realized by cooperation of the thermometer 143 and the heater 142 or cooperation of the thermometer 151 and the heater 150.

In the second sulfuric acid electrolysis unit 7D, the first path and the second path relating to the regeneration tank 20A and the regeneration tank 20A may be provided, and the first path and the second path relating to the regeneration tank 20B and the regeneration tank 20B may be omitted.

### 2-3. Third Embodiment of Regeneration Unit 7

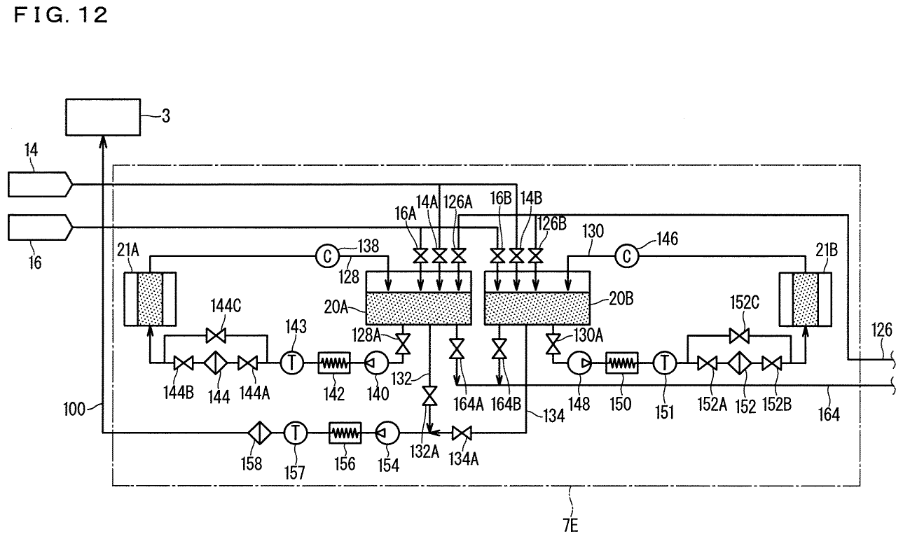

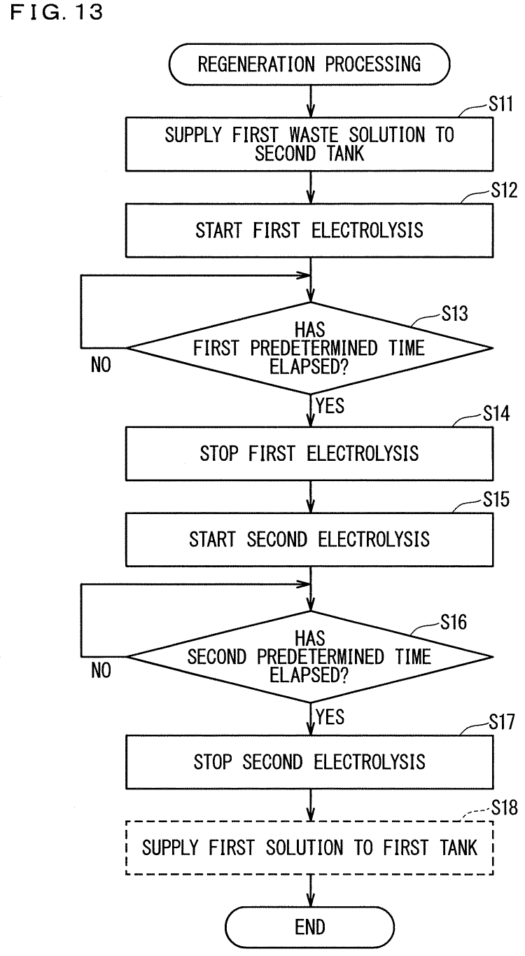

FIG. 12 is a schematic diagram exemplifying a configuration of a third sulfuric acid electrolysis unit 7E. A third embodiment of the regeneration unit 7 includes the second recovery unit 7C (see FIG. 10), the third sulfuric acid electrolysis unit 7E, the recovery pipe 126, and the discharged liquid pipe 164. The recovery pipe 126 and the discharged liquid pipe 164 can be considered to be shared by the second recovery unit 7C and the third sulfuric acid electrolysis unit 7E, or can be considered to be included in either the second recovery unit 7C or the third sulfuric acid electrolysis unit 7E.

The second recovery unit 7C and the third sulfuric acid electrolysis unit 7E are connected by the recovery pipe 126 and the discharged liquid pipe 164.

Similarly to the second sulfuric acid electrolysis unit 7D, the third sulfuric acid electrolysis unit 7E also performs the first electrolysis and the second electrolysis. Also in the third embodiment, the second recovery unit 7C operates similarly to that in the second embodiment.

The third sulfuric acid electrolysis unit 7E has a configuration in which valves 144A, 144B, 144C, 152A, 152B, and 152C are added to the first sulfuric acid electrolysis unit 7B (see FIG. 9). For example, all of the valves 144A, 144B, 144C, 152A, 152B, and 152C are on-off valves, and opening and closing of these are controlled by the control unit 90.

The valves 144A and 144B are provided in the circulation pipe 128. The valve 144A is arranged between the thermometer 143 and the filter 144 in the circulation pipe 128. The valve 144B is arranged between the electrolysis cell 21A and the filter 144 in the circulation pipe 128. The circulation pipe 128 is branched by bypassing the valve 144A between the thermometer 143 and the electrolysis cell 21A, and the valve 144C is provided at the branch. The valve 144C can be said to be provided in parallel to series connection of the valve 144A and the filter 144, can be said to be provided in parallel to series connection of the valve 144B and the filter 144, and can be said to be provided in parallel to series connection of the valves 144A and 144B and the filter 144.

The valves 152A and 152B are provided in the circulation pipe 130. The valve 152A is arranged between the thermometer 151 and the filter 152 in the circulation pipe 130. The valve 152B is arranged between the electrolysis cell 21B and the filter 152 in the circulation pipe 130. The circulation pipe 130 is branched by bypassing the valve 152A between the thermometer 151 and the electrolysis cell 21B, and the valve 152C is provided at the branch. The valve 152C can be said to be provided in parallel to series connection of the valve 152A and the filter 152, can be said to be provided in parallel to series connection of the valve 152B and the filter 152, and can be said to be provided in parallel to series connection of the valves 152A and 152B and the filter 152.

Similarly to the second embodiment, both the regeneration tanks 20A and 20B can be said to be the second tanks or the third tanks.

The fifth solution is supplied from the recovery pipe 126 to the regeneration tank 20A via the valve 126A, and to the regeneration tank 20B via the valve 126B. Both the valves 126A and 126B adjust a flow rate of the supplied fifth solution under control of the control unit 90.

In the third sulfuric acid electrolysis unit 7E, the pump 140 and the electrolysis cell 21A operate in a state where either or both of the valves 144A and 144B are closed and the valves 128A and 144C are opened, and the first electrolysis is performed on the first waste solution contained in the fifth solution stored in the regeneration tank 20A.

Since the fifth solution stored in the regeneration tank 20A is blocked by any one of the valves 144A and 144B, the fifth solution is fed by operation of the pump 140 in the circulation pipe 128 via the valves 128A and 144C without passing through the filter 144. The first waste solution contained in the fifth solution undergoes the first electrolysis by the electrolysis cell 21A. As the first electrolysis progresses, an amount of the first waste solution in the regeneration tank 20A decreases, and an amount of the third solution increases.

The first electrolysis using the regeneration tank 20A is completed, for example, based on lapse of time, similarly to the first electrolysis in the first recovery unit 7A. At a time point at which the first electrolysis is completed, the regeneration tank 20A substantially stores the fourth solution.

After the first electrolysis is completed, the valves 128A, 144A, and 144B are opened, and the pump 140 and the electrolysis cell 21A are operated in a state where the valve 144C is closed, so that the second electrolysis is performed on the third solution contained in the fourth solution stored in the regeneration tank 20A.

Since the fourth solution stored in the regeneration tank 20A is blocked by the valve 144C, the fourth solution is fed by operation of the pump 140 in the circulation pipe 128 via the valves 128A, 144A, and 144B without bypassing the filter 144. While the fourth solution is filtered by the filter 144, the third solution contained in the fourth solution undergoes the second electrolysis by the electrolysis cell 21A. As the second electrolysis progresses, an amount of the third solution in the regeneration tank 20A decreases and an amount of the first solution increases.

The second electrolysis using the regeneration tank 20A is completed, for example, based on lapse of time, similarly to the second electrolysis in the first sulfuric acid electrolysis unit 7B. At a time point at which the second electrolysis is completed, the regeneration tank 20A substantially stores the first solution.

From such operation, it can be said that the electrolysis cell 21A is the first electrolyzer that performs the first electrolysis and is also the second electrolyzer that performs the second electrolysis.

In the third sulfuric acid electrolysis unit 7E, the pump 148 and the electrolysis cell 21B operate in a state where either or both of the valves 152A and 152B are closed and the valves 130A and 152C are opened, and the first electrolysis is performed on the first waste solution contained in the fifth solution stored in the regeneration tank 20B.

Since the fifth solution stored in the regeneration tank 20B is blocked by any one of the valves 152A and 152B, the fifth solution is fed by operation of the pump 148 in the circulation pipe 130 via the valves 130A and 152C without passing through the filter 152. The first waste solution contained in the fifth solution undergoes the first electrolysis by the electrolysis cell 21B. As the first electrolysis progresses, an amount of the first waste solution in the regeneration tank 20B decreases, and an amount of the third solution increases.

The first electrolysis using the regeneration tank 20B is completed, for example, based on lapse of time, similarly to the first electrolysis in the first recovery unit 7A. At a time point at which the first electrolysis is completed, the regeneration tank 20B substantially stores the fourth solution.

After the first electrolysis is completed, the valves 130A, 152A, and 152B are opened, and the pump 148 and the electrolysis cell 21B are operated in a state where the valve 152C is closed, so that the second electrolysis is performed on the third solution contained in the fourth solution stored in the regeneration tank 20B.

Since the fourth solution stored in the regeneration tank 20B is blocked by the valve 152C, the fourth solution is fed by operation of the pump 148 in the circulation pipe 130 via the valves 130A, 152A, and 152B without bypassing the filter 152. While the fourth solution is filtered by the filter 152, the third solution contained in the fourth solution undergoes the second electrolysis by the electrolysis cell 21B. As the second electrolysis progresses, an amount of the third solution in the regeneration tank 20B decreases and an amount of the first solution increases.

The second electrolysis using the regeneration tank 20B is completed, for example, based on lapse of time, similarly to the second electrolysis in the first sulfuric acid electrolysis unit 7B. At a time point at which the second electrolysis is completed, the regeneration tank 20B substantially stores the first solution.

From such operation, it can be said that the electrolysis cell 21B is the first electrolyzer that performs the first electrolysis and is also the second electrolyzer that performs the second electrolysis.

Operation of the third sulfuric acid electrolysis unit 7E other than the first electrolysis by the electrolysis cells 21A and 21B is similar to operation of the first sulfuric acid electrolysis unit 7B.

The first electrolysis using the regeneration tank 20A and the first electrolysis using the regeneration tank 20B may be performed in parallel. The second electrolysis using the regeneration tank 20A and the second electrolysis using the regeneration tank 20B may be performed in parallel.

The second electrolysis using the regeneration tank 20B may be performed while the first electrolysis using the regeneration tank 20A is performed. The first electrolysis using the regeneration tank 20B may be performed while the second electrolysis using the regeneration tank 20A is performed. Performing the first electrolysis and the second electrolysis in a complementary manner by the regeneration tanks 20A and 20B contributes to efficiency improvement of the regeneration processing more than a case where only one of the regeneration tanks 20A and 20B is employed in the third sulfuric acid electrolysis unit 7E.

In the third embodiment, for example, the valves 128A and 144C, the electrolysis cell 21A, and the circulation pipe 128 are considered as the first path through which the second solution circulates to and from the regeneration tank 20A. For example, the valves 130A and 152C, the electrolysis cell 21B, and the circulation pipe 130 are considered as the first path through which the second solution circulates to and from the regeneration tank 20B.

In the third embodiment, for example, the valve 128A, the filter 144, the valves 144A and 144B, the electrolysis cell 21A, and the circulation pipe 128 are considered as the second path for generating the first solution while filtering the third solution by the filter 144. For example, the valve 130A, the filter 152, the valves 152A and 152B, the electrolysis cell 21B, and the circulation pipe 130 are considered as the second path for generating the first solution while filtering the third solution by the filter 152.

Also in the third embodiment, similarly to the first embodiment, the supply pipes 100, 132, and 134 are considered as the third path for supplying the first solution from the regeneration unit 7, more specifically, the third sulfuric acid electrolysis unit 7E to the supply tank 10.

Also in the third embodiment, life of the filters 144 and 152 is extended similarly to the first embodiment.

The third embodiment does not require the electrolysis cell 21C in the first embodiment, and does not require the electrolysis cells 21D and 21E in the second embodiment. From this viewpoint, the third embodiment has an advantage of being easily obtained at low cost as compared with both the first embodiment and the second embodiment.

In the third embodiment, the electrolysis cell 21C in the first embodiment is not employed, the electrolysis cells 21D and 21E in the second embodiment are not employed, and both the electrolysis cells 21A and 21B serve as the first electrolysis cell and the second electrolysis cell. From this viewpoint, both the first embodiment and the second embodiment have an advantage that the electrolysis cells 21A and 21B are less likely to deteriorate (suppression of deterioration) than the third embodiment.

The first embodiment has an advantage over the third embodiment from the viewpoint that regeneration processing can be made unnecessary for the first solution supplied from the recovery pipe 110 and the supply pipe 102 to the regeneration unit 7.

Also in the third embodiment, as in the first embodiment, for example, the second electrolysis is performed at higher temperature than the first electrolysis. Such temperature control can be realized by cooperation of the thermometer 143 and the heater 142 or cooperation of the thermometer 151 and the heater 150.

In the third sulfuric acid electrolysis unit 7E, the first path and the second path relating to the regeneration tank 20A and the regeneration tank 20A may be provided, and the first path and the second path relating to the regeneration tank 20B and the regeneration tank 20B may be omitted.

### <3. Sulfuric Acid Regeneration Processing>

The substrate processing apparatus 1 operates as described above, and the first solution is generated from the first waste solution. The first solution is supplied to the supply tank 10 as post-regeneration sulfuric acid to be used for generation of treatment solution.

FIG. 13 is a flowchart exemplifying regeneration processing for obtaining the first solution from the first waste solution. The regeneration processing includes Steps S11, S12, S13, S14, S15, S16, and S17. The sulfuric acid regeneration processing may include Step S18.

Step S11 is a step of supplying the first waste solution to the second tank. In accordance with the first embodiment, in Step S11, the first waste solution is supplied from the recovery pipe 124 to the recovery tank 30A via the valve 124A, and to the recovery tank 30B via the valve 124B (see FIG. 8). In accordance with the second embodiment and the third embodiment, in Step S11, the first waste solution is supplied from the recovery pipe 124 to the recovery tank 30C via the valve 124C (see FIG. 10).

Step S12 is a step of starting the first electrolysis. In accordance with the first embodiment, in Step S12, the valves 124A, 124B, 125D, 164E, and 164F are closed, the valve 125C is opened, and the pump 136 and the electrolysis cell 21C are operated. In a case where the first electrolysis is performed using the recovery tank 30A, the valves 125A and 136A are opened. In a case where the first electrolysis is performed using the recovery tank 30B, the valves 125B and 136B are opened (see FIG. 8).

In the first electrolysis in the first embodiment, closing the valve 136D contributes to not using the first solution stored in the recovery tank 30D for the first electrolysis, so that load on the electrolysis cell 21C is reduced.

In accordance with the second embodiment, the valves 132A and 134A are closed in Step S12. When the first electrolysis is performed using the regeneration tank 20A, in Step S12, the valves 138A and 142A are closed, the valves 128A and 140A are opened, and the pump 140 and the electrolysis cell 21D are operated. In a case where the first electrolysis is performed using the regeneration tank 20B, in Step S12, the valves 146A and 150A are closed, the valves 130A and 148A are opened, and the pump 148 and the electrolysis cell 21E are operated (see FIG. 11).

In accordance with the third embodiment, the valves 132A and 134A are closed in Step S12. In a case where the first electrolysis is performed using the regeneration tank 20A, in Step S12, either or both of the valves 144A and 144B are closed, the valve 144C is open, and the pump 140 and the electrolysis cell 21A are operated. In a case where the first electrolysis is performed using the regeneration tank 20B, in Step S12, either or both of the valves 152A and 152B are closed, the valve 152C is open, and the pump 148 and the electrolysis cell 21B are operated (see FIG. 12).

After the first electrolysis starts in Step S12, Step S13 is executed. In Step S13, whether first predetermined time has elapsed after execution of Step S12 is determined. Step S13 is repeatedly executed until a result of the determination becomes positive.

The first electrolysis started in Step S12 is continued until the first predetermined time elapses. The first predetermined time is time estimated to be required for the first electrolysis. It can also be said that the first predetermined time is time in which an amount of an organic substance in the first waste solution or the proportion of an organic substance is estimated to be less than a predetermined value. When a result of the determination in Step S13 is positive, Step S14 is executed.

Step S14 is a step of stopping the first electrolysis. According to the first embodiment, for example, operation of the electrolysis cell 21C is stopped (see FIG. 8). In accordance with the second embodiment, when the first electrolysis using the regeneration tank 20A is stopped, for example, operation of the electrolysis cell 21D is stopped, and when the first electrolysis using the regeneration tank 20B is stopped, for example, operation of the electrolysis cell 21E is stopped (see FIG. 11). In accordance with the third embodiment, when the first electrolysis using the regeneration tank 20A is stopped, for example, operation of the electrolysis cell 21A is stopped, and when the first electrolysis using the regeneration tank 20B is stopped, for example, operation of the electrolysis cell 21B is stopped (see FIG. 12).

In the third embodiment, the electrolysis cells 21A and 21B operate in both the first electrolysis and the second electrolysis. Since the second electrolysis is executed after the first electrolysis, the electrolysis cells 21A and 21B do not necessarily have to be stopped in Step S14.

Step S15 is a step of starting the second electrolysis. In accordance with the first embodiment, in Step S15, the valve 125C (alternatively, also the valves 125A and 125B) is closed. In a case where the first electrolysis using the recovery tank 30A is completed, the valve 136A is opened, and in a case where the first electrolysis using the recovery tank 30B is completed, the valve 136B is opened, and the pump 136 is operated in both cases (see FIG. 8).

In Step S15, the valves 132A and 134A are closed. In a case where the second electrolysis is performed using the regeneration tank 20A, the valve 128A is opened, and the pump 140 and the electrolysis cell 21A are operated. In a case where the second electrolysis is performed using the regeneration tank 20B, the valve 130A is opened and the pump 148 and the electrolysis cell 21B are operated (see FIG. 9).

In accordance with the second embodiment, in Step S15, the valves 132A and 134A are closed. In a case where the second electrolysis using the regeneration tank 20A is performed, the valves 138A and 142A are opened, and the pump 140 and the electrolysis cell 21A are operated. In a case where the second electrolysis using the regeneration tank 20B is performed, the valves 146A and 150A are opened, and the pump 148 and the electrolysis cell 21B are operated (see FIG. 11).

In accordance with the third embodiment, in Step S15, the valves 132A and 134A are closed. In a case where the second electrolysis using the regeneration tank 20A is performed, the valves 144A and 144B are opened, the valve 144C is closed, and the pump 140 and the electrolysis cell 21A are operated. In a case where the second electrolysis using the regeneration tank 20B is performed, the valves 152A and 152B are opened, the valve 152C is closed, and the pump 148 and the electrolysis cell 21B are operated (see FIG. 12).

After the second electrolysis is started in Step S15, Step S16 is executed. In Step S16, whether second predetermined time has elapsed after execution of Step S15 is determined. Step S16 is repeatedly executed until a result of the determination becomes positive.

The second electrolysis started in Step S15 is continued until the second predetermined time elapses. The second predetermined time is time estimated to be required for the second electrolysis. The second predetermined time can be said to be time during which an amount or concentration of the obtained first solution, specifically, an amount or concentration of peroxydisulfate ions, exceeds a predetermined value. When a result of the determination in Step S16 is positive, Step S17 is executed.

Step S17 is a step of stopping the second electrolysis. In accordance with all of the first embodiment, the second embodiment, and the third embodiment, when the second electrolysis using the regeneration tank 20A is stopped, operation of the electrolysis cell 21A is stopped, for example, and when the second electrolysis using the regeneration tank 20B is stopped, operation of the electrolysis cell 21B is stopped, for example (see FIGS. 9, 11, and 12).

A case where the sulfuric acid regeneration processing further includes Step S18 is also assumed. Step S18 is a step of supplying the first solution to the first tank after Step S17 is executed. In accordance with all of the first embodiment, the second embodiment, and the third embodiment, for example, the valves 132A and 134A are opened and the pump 154 is operated in Step S17.

From the above viewpoint, the substrate processing method according to the present disclosure is a method of performing processing on a substrate by using treatment solution, and can be considered to include, for example, a step of supplying treatment solution containing the first solution containing a peroxydisulfate ion to the substrate W, a step of supplying the waste solution to the second tank (corresponding to the recovery tanks 30A and 30B in accordance with the first embodiment, and the regeneration tanks 20A and 20B in accordance with the second embodiment and the third embodiment) that stores the second solution, and a step of performing the regeneration processing.

The regeneration processing can be considered to include two steps, the first electrolysis and the second electrolysis. The first electrolysis generates the third solution with respect to the second solution in the first path in which the second solution circulates to and from the second tank. The second electrolysis generates the first solution while filtering the third solution through the filters 144 and 152 in the second path having the filters 144 and 152. The first solution thus generated is reused as treatment solution.

### <4. Variation>

There may be a case where the concentration meters 138 and 146 can measure concentration of peroxydisulfuric acid separately from concentration of sulfuric acid and concentration of peroxymonosulfuric acid (for example, spectroscopic analysis or the like). In the determination in Step S16, degree of deactivation of peroxydisulfuric acid is determined. In the above case, a determination condition in Step S16 may be changed to “whether concentration of peroxydisulfuric acid is less than predetermined concentration”.

In place of the second recovery unit 7C in the second embodiment and the third embodiment, a configuration in which the circulation pipe 125, the electrolysis cell 21C, and the valves 125A, 125B, and 125C are removed from the first recovery unit 7A may be used.

Note that it goes without saying that all or a part of configurations of the above-described embodiments and various variations can be appropriately combined within a range not contradictory.

### EXPLANATION OF REFERENCE SIGNS

1: substrate processing apparatus
10: supply tank
20A, 20B: regeneration tank
30A, 30B: recovery tank
21A, 21B, 21C, 21D, 21E: electrolysis cell
100, 132, 134: supply pipe
125, 128, 130: circulation pipe
106B: nozzle
125A, 125B, 125C, 128A, 130A, 136A, 136B, 140A, 148A, 144A, 144B, 144C, 152A, 152B, 152C: valve
144, 152: filter
W: substrate

1. A substrate processing apparatus which is an apparatus for performing processing on a substrate by using treatment solution, the substrate processing apparatus comprising:
a nozzle that is supplied with first solution containing a peroxydisulfate ion and supplies said treatment solution containing said first solution to said substrate;
a first tank that stores said first solution;
a second tank that is supplied with waste solution, which is said treatment solution after being used for said processing on said substrate, and stores second solution;
a first path through which said second solution circulates to and from said second tank, and in which third solution is generated by performing first electrolysis on said second solution;
a second path including a filter, in which said first solution is generated by performing second electrolysis while said third solution is filtered by said filter; and
a third path for supplying said first solution to said first tank.

2. The substrate processing apparatus according to claim 1, wherein
said first path includes a first electrolyzer that performs said first electrolysis, and
said second path includes
a third tank that stores said third solution, and
a second electrolyzer through which said third solution circulates to and from said third tank, said second electrolyzer performing said second electrolysis.

3. The substrate processing apparatus according to claim 1, wherein
said second tank is included in both said first path and said second path, and
said third solution circulates to and from said second tank through said second path.

4. The substrate processing apparatus according to claim 3, wherein
said first path includes a first electrolyzer that performs said first electrolysis, and
said second path includes a second electrolyzer that performs said second electrolysis.

5. The substrate processing apparatus according to claim 3, wherein
said second path further includes a first on-off valve connected in series to said filter,
said first path includes
a second on-off valve provided in parallel to series connection of said filter and said first on-off valve, and
an electrolyzer also shared by said second path, and
said electrolyzer
performs said first electrolysis when said first on-off valve is closed and said second on-off valve is opened, and
performs said second electrolysis when said second on-off valve is closed and said first on-off valve is opened.

6. The substrate processing apparatus according to claim 1, wherein said second electrolysis is executed at higher temperature than said first electrolysis.

7. A substrate processing method which is a method of performing processing on a substrate by using treatment solution, the substrate processing method comprising:
supplying said treatment solution containing first solution containing a peroxydisulfate ion to said substrate;
supplying waste solution, which is said treatment solution after being used for said processing on said substrate, to a tank that stores second solution;
generating third solution by performing first electrolysis on said second solution in a first path through which said second solution circulates to and from said tank; and
generating, in a second path including a filter, said first solution by performing second electrolysis while filtering said third solution by said filter.
